(19) United States
(12) Patent Application Publication
(10) Pub. No.: US 2014/0010602 A1
(43) Pub. Date: Jan. 9, 2014

(54) METHOD FOR IMAGING MULTIPLE SIDES OF OBJECTS

(71) Applicants: Shy Cohen, Yokneam (IL); Ilan Greenberg, Haifa (IL)

(72) Inventors: Shy Cohen, Yokneam (IL); Ilan Greenberg, Haifa (IL)

(21) Appl. No.: 13/726,633

(22) Filed: Dec. 26, 2012

Related U.S. Application Data
(63) Continuation of application No. 12/866,377, filed on Jan. 10, 2011.

(51) Int. Cl. B65G 51/02; G01R 31/01

(52) U.S. Cl. CPC B65G 51/02; G01R 31/016
USPC 406/34

(57) ABSTRACT

A method for acquiring multiple images of objects, the method includes: longitudinally transferring objects through multiple tunnels of a first, second third and fourth longitudinal transferors to first, second and fourth imaging areas and rotating the object about their longitudinal axis between imaging areas; acquiring images of first, second, third and fourth sides of the object at the first, second, third and fourth imaging areas respectively; wherein at least one longitudinal transferor has a movable portion that when placed in a certain position exposes at least a substantial portion of at least one tunnel.

### RELATED APPLICATIONS

The present invention is a continuation of U.S. patent Ser. No. 12/866,377 which claims the priority of PCT patent application serial number PCT/IL2009/000134 international filing date of Feb. 5, 2009 which claims the benefit of U.S. provisional patent Ser. No. 61/026,783, filing date Feb. 7, 2008, U.S. provisional patent Ser. No. 61/118,447, filing date Nov. 27, 2008 and Japanese patent serial number 2008-311277 filing date Dec. 5, 2008, all being incorporated by reference.

### FIELD OF THE INVENTION

The present invention relates to systems and method for inspecting objects such as electrical objects and especially small and elongated electrical objects such as but not limited to capacitors.

### BACKGROUND OF THE INVENTION

External appearance is one of the inspection methods that are done by comparing images of an inspected object with a reference image. In case of one or two sides imaging e.g., wafers or Printed Circuit Boards an image is captured from a perpendicular view or from a below view for inspection, which are simple tasks.

In the case of a six-faced object, the procedure is more complicated. Such an inspection is needed for many products and some of these products are very small or in large quantities. For instance, there is a need to inspect the whole sides of electrical objects that are used in microelectronic production (Ceramic Capacitors, Chips and Resistors); a wide range of defects such as dimensional measurements, ceramic defects and termination defects can be recognized by using automatic optical inspection systems.

Systems that use imaging of the overall sides of an object were disclosed in U.S. Pat. No. 4,912,318 “inspection Equipment for Small Bottles” and U.S. Pat. No. 4,219,269 “External Appearance Inspection System” both assigned to Kajiura et al. additionally, these systems have some shortcomings.

Objects such as but not limited to small capacitors can be damaged during the inspection process or before the inspection process. Dirt as well as objects pieces can jam an inspection device.

The measurement of absolute electrical characteristics of objects, such as capacitors is a relatively long process that limits the throughput of the inspection process.

There is a growing need to provide efficient systems and methods for inspecting objects.

### SUMMARY OF THE INVENTION

A system for acquiring multiple images of objects, the system includes: four longitudinal transferor that include multiple tunnels through which the objects propagate to four imaging areas; wherein the four longitudinal transferor utilize gas pressure differentials to convey the objects through the tunnels; wherein at least one longitudinal transferor has a movable portion that when placed in a certain position exposes at least a substantial portion of at least one tunnel; three rotation modules configured to rotate objects about a longitudinal axis of the objects; wherein each rotation element is located between two longitudinal transferor; and imager, configured to obtain, in each of the four imaging areas, an image of the objects.

Conveniently, the movable portion is transparent and the imager is configured to obtain at least an image of one of the faces of the objects through the movable portion.

Conveniently, each longitudinal transferor includes a movable portion that exposes all tunnels of the longitudinal transferor.

Conveniently, the system includes an electrical testing module configured to compare between an electrical characteristic of an object that is imaged by the imager and an electrical characteristic of a reference object to provide an electrical test result.

Conveniently, the objects are capacitors; wherein the system includes an electrical testing module configured to compare between a capacitance of a capacitor that was imaged by the imager and a capacitance of a reference capacitor to provide an electrical test result.

Conveniently, each of the four longitudinal transferors includes multiple tunnels, each including substantially vertical sidewalls.

Conveniently, each of the four longitudinal transferor forms an imaging area and wherein each of the four longitudinal transferors is much longer than each rotation module.

Conveniently, the system includes a sorting unit adapted to sort in parallel multiple objects according to their functionality.

Conveniently, the sorting unit includes multiple groups of output conduits and multiple gas driven control elements; wherein each gas driven control element is associated with a group of output conduits; and wherein each gas driven control element is adapted to direct an objects to an output conduit of an associated group in response to a functionality of the object.

Conveniently, the system further includes a supply element that includes an inlet and an outlet; wherein the inlet is positioned above the outlet and wherein the outlet is positioned above multiple tunnels of a first longitudinal transferor; wherein a object that enters the inlet falls towards the outlet.

Conveniently, the system further includes a lateral transferor adapted to transfer the objects to an additional imaging area in a lateral manner and wherein the imager is configured to obtain images of two opposite sides of the objects that differ from sides of the objects that are imaged at the four imaging areas.

Conveniently, system includes optical components that direct light from the opposite sides of the objects towards the imager.

Conveniently, the multiple tunnels are parallel to each other and the four longitudinal transferor and the three rotation modules are located at a same plane.

Conveniently, the movable portion is detachably coupled to another portion of the longitudinal transferor in which the tunnels are formed.

A method for acquiring multiple images of objects, the method includes: longitudinally transferring objects through multiple tunnels of a first longitudinal transferor to a first imaging area; wherein the longitudinally transferring utilizes gas pressure differentials; obtaining an image of a first side of the objects at the first imaging area; rotating the object by a first rotation module that rotates the objects about a longitudinal axis of the objects; longitudinally transferring objects through multiple tunnels of a second longitudinal transferor to a second imaging area; obtaining an image of a second side of the objects at the second imaging area; rotating the objects by a second rotation module that rotates the objects about the longitudinal axis of the objects; longitudinally transferring objects through multiple tunnels of a third longitudinal transferor to a third imaging area; obtaining an image of a third side of the objects at the third imaging area; rotating the object by a third rotation module that rotates the objects about the longitudinal axis of the objects; longitudinally transferring objects through multiple tunnels of a fourth longitudinal transferor to a fourth imaging area; obtaining an image of a fourth side of the objects at the fourth imaging area; wherein at least one longitudinal transferor has a movable portion that when placed in a certain position exposes at least a substantial portion of at least one tunnel.

The method can include moving the movable portion to the certain position and cleaning the tunnels.

The method can include imaging the multiple objects via a transparent movable portion.

The method can include electrically testing an electrical object by comparing an electrical characteristic of the object to an electrical characteristic of a reference object to provide an electrical test result.

The objects can be capacitors and the method can include comparing a capacitance of a capacitor to a capacitance of a reference capacitor.

The method can include laterally transferring objects through multiple tunnels, each includes substantially vertical sidewalls.

The method can include transferring objects through multiple tunnels of the four longitudinal transferors that form four imaging areas; wherein each of the four longitudinal transferors is much longer than each rotation module.

The method can further include sorting, in parallel, multiple objects according to their functionality.

A system is provided. It includes a substantially horizontal space adapted to receive objects but prevent objects from being piled one over the other; multiple tunnels and multiple gas openings configured to convey a gas pressure that induces objects to enter the tunnels.

The system can include additional openings configured to direct gas into the tunnels such as to prevent objects from moving back to the substantially horizontal space.

The system can include a sorting unit and a movable portion that when placed at a certain position exposed the tunnels.

The substantially horizontal space can be a beveled space.

The multiple tunnels can include narrow portions that block objects that are wider than an allowable width.

The system can include a movable portion that when placed at a certain position exposes the tunnels.

The system can include an electrical testing module configured to measure an electrical characteristic of the objects.

The system can include an electrical testing module configured to compare between an electrical characteristic of an object that is imaged by the imager and an electrical characteristic of a reference object to provide an electrical test result.

The system can include gas openings that convey gas that moves objects towards the multiple tunnels.

The system can include gas openings that convey gas pulses that induce objects to enter the multiple tunnels.

The system can include gas openings that prevent objects from being sent from a tunnel to the substantially horizontal space.

A system, including: a substantially horizontal space adapted to receive objects; multiple tunnels and multiple gas openings configured to convey a gas pressure that induces objects to enter the tunnels; and an electrical testing module configured to compare between an electrical characteristic of an object that is imaged by the imager and an electrical characteristic of a reference object to provide an electrical test result.

A method for sorting objects, the method comprises: receiving objects by a substantially horizontal space while preventing objects from being piled one over the other; providing the objects to multiple tunnels by supplying gas to multiple gas openings; and generating a gas pressure that induces objects to enter the tunnels.

The method can include directing gas via additional openings into the tunnels such as to prevent objects from moving back to the substantially horizontal space.

The method can include sorting the objects and moving a movable portion to expose the tunnels.

The method can include receiving the object by a beveled space.

The method can include blocking, by narrow portions of the multiple tunnels, objects that are wider than an allowable width.

The method can include moving a movable portion to expose the tunnels.

The method can include measuring an electrical characteristic of the objects.

The method can include comparing between an electrical characteristic of an object that is imaged by the imager and an electrical characteristic of a reference object to provide an electrical test result.

The method can include conveying gas through gas openings so as to move objects towards the multiple tunnels.

The method can include conveying gas pulses through gas openings to induce objects to enter the multiple tunnels.

The method can include introducing gas to the multiple tunnels so as to prevent objects from being sent from a tunnel to the substantially horizontal space.

A method that includes: receiving objects by a substantially horizontal space; conveying gas through multiple gas openings to induce objects to enter the tunnels; and comparing between an electrical characteristic of an object that is imaged by the imager and an electrical characteristic of a reference object to provide an electrical test result.

### BRIEF DESCRIPTION OF THE DRAWINGS

The invention is herein described, by way of example only, with reference to the accompanying drawings. With specific reference now to the drawings in detail, it is stressed that the particulars shown are by way of example and for purposes of illustrative discussion of various embodiments of the present invention. In the figures:

FIGS. 1a-1b illustrate a system for imaging objects according to an embodiment of the invention;

FIGS. 2a-2c and 3 illustrate portions of a system for imaging objects according to an embodiment of the invention;

FIG. 4 illustrates a portion of two longitudinal transferors and multiple stopping elements according to an embodiment of the invention;

FIGS. 5a-5f illustrate a supply element according to an embodiment of the invention;

FIG. 6a-6d illustrate portions of a sorting unit according to an embodiment of the invention;

FIGS. 7-9 illustrate various configurations of a sorting element according to various embodiments of the invention;

FIG. 10a-10b illustrate rotation modules according to an embodiment of the invention;

FIG. 11 illustrates a portion of a system according to another embodiment of the invention;

FIGS. 12 and 13 illustrate transferring elements, a suction element, a object conduit and few objects according to an embodiment of the invention;

FIG. 14 illustrates an electrical tester, according to an embodiment of the invention;

FIG. 15 is a flow chart of a method for imaging objects according to an embodiment of the invention;

FIG. 16 is a flow chart of a method for imaging objects according to an embodiment of the invention;

FIG. 17 is a flow chart of a method for imaging objects according to an embodiment of the invention;

FIG. 18 illustrates a system for imaging objects according to an embodiment of the invention;

FIG. 19 illustrates a system for imaging objects according to an embodiment of the invention;

FIG. 20 illustrates a system for electrical testing according to an embodiment of the invention; and

FIGS. 21-22 illustrate systems according to various embodiments of the invention.

### DETAILED DESCRIPTION OF THE DRAWINGS

In the following specification, the invention will be described with reference to specific examples of embodiments of the invention. It will, however, be evident that various modifications and changes may be made therein without departing from the broader spirit and scope of the invention as set forth in the appended claims.

Because the apparatus implementing the present invention is, for the most part, composed of electronic objects and circuits known to those skilled in the art, circuit details will not be explained in any greater extent than that considered necessary as illustrated above, for the understanding and appreciation of the underlying concepts of the present invention and in order not to obfuscate or distract from the teachings of the present invention.

Multiple sides of an object such as an electrical object and especially a small elongated electrical object are imaged. The length of the small elongated electrical objects usually does not exceed few millimeters. The following description will refer to such objects. It is noted that these objects are conveniently small elongated electrical objects such as millimetric capacitors that later form a part of electrical circuits such as PCBs. Such milimetric capacitors can be but are not limited to multi layer ceramic capacitors (MLCCs) that are 0.06 Inch long and 0.03 Inch wide, MLCCs that are 0.04 Inch long and 0.02 Inch wide, MLCCs that are 0.02 Inch long and 0.01 Inch wide and MLCCs that are 0.01 Inch long and 0.005 Inch wide, as well as milimmetric resistors.

Multiple sides (or faces) of objects are imaged and these images are then processed to determine, for example, the functionality of these objects. Conveniently, many objects can be imaged per second by illuminating multiple sides of objects and imaging these sides.

A robust and high throughput imaging system includes multiple tunnels through which objects can propagate. The imaging system includes one or more movable portions that when moved expose tunnels of the imaging system and facilitate cleaning of these channels. Conveniently, the movable portions are transparent and the objects can be imaged through the movable portions.

The movable portion can be rigid and does not include any optical elements that require fine adjustments after being placed back to its initial position.

The imaging includes obtaining an image of one side of the objects at a time and does not require time consuming optical path adjustments required when imaging multiple sides at a time. This allows moving movable portions during cleaning and then placing them back without performing any adjustments or calibrations of the optical components of the imaging system.

Yet according to another embodiment of the invention the objects are electrically tested by comparing one or more electrical characteristic of these objects to one or more electrical characteristic of reference objects. These tests are faster than so-called absolute tests.

The capacitance of capacitors can be compared to the capacitance of reference capacitors at a short time and without using costly testing equipment.

The objects can be resistors and their resistance can be compared to the resistance of reference resistors.

The difference between the compared electrical tested objects can be used to classify the objects.

Conveniently, a non-comparison based electrical test can be applied.

According to another embodiment of the invention, images of lateral sides of small elongated electrical circuits, at high throughput, can be achieved by laterally transferring small elongated electrical objects.

The objects can be conveyed in tunnels by using gas differences—thus reducing the chances that the small elongated electrical circuits are damaged during the inspection and transfer sessions.

It is noted that the system includes multiple tunnels. These tunnels are equivalent to pipes, lines, trenches or any other elements through which objects can propagate, especially sealed or partially sealed elements. The tunnels can have a square cross section or a round cross section or any combination of rectangular shapes.

They are conveniently not equipped with folding mirrors, sloped minors or other optics that allow obtaining side views of the objects located within them. A side view is a view that is not taken from a side that faces an imager.

The tunnels can be very small—and can be slightly larger than the objects that propagate within them. They can be located in close proximity to each other. For example—each tunnel can be about two millimeters wide and spaced apart from another tunnel by less then three millimeters.

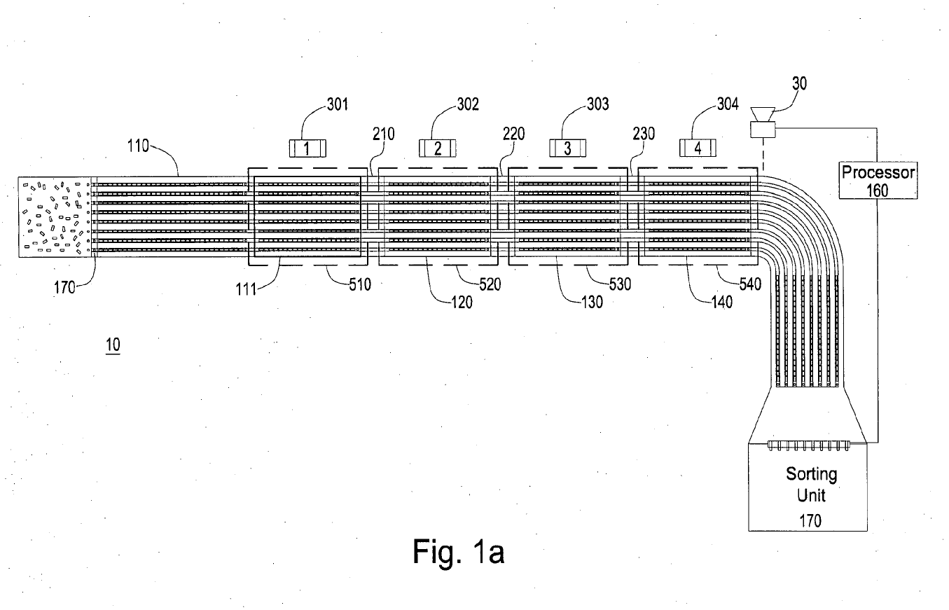

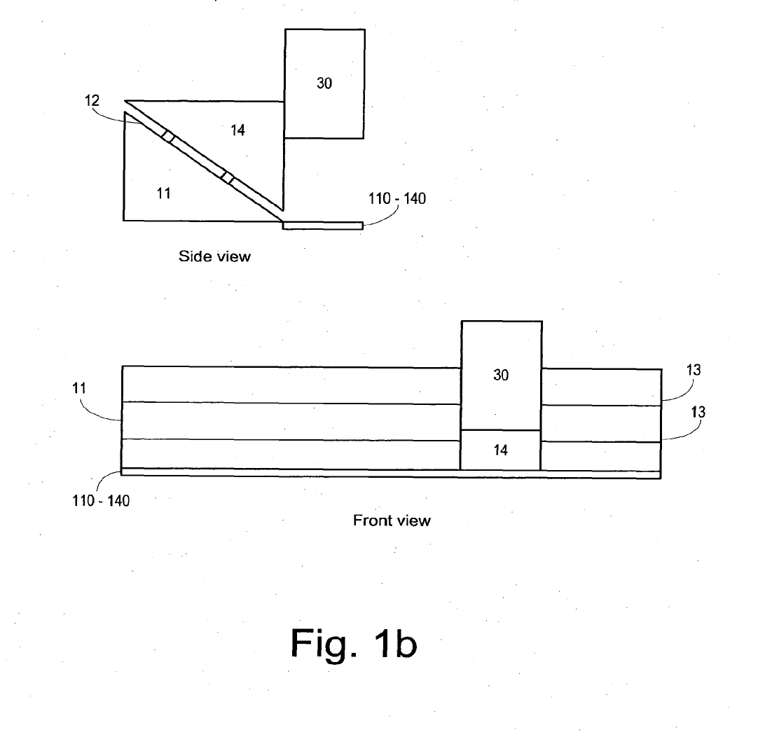

Referring to FIG. 1a which is a schematic illustration of system 10. System 10 includes imager 30 that can obtain images of objects located in first imaging area 510, second imaging area 520, third imaging area 530 and fourth imaging area 540. Imager 30 can obtain these images in a serial manner or in parallel.

It is noted that system 10 can include multiple image sensors, each positioned above one or more imaging area but it can also include a single image sensor (as illustrated in FIG. 1) that obtains images from one imaging area after the other.

Imager 30 can be moved from one imaging area to another in various manners. For example, as illustrated in FIG. 1b—imager 30 is can be moved from location to the other by a combination of a supporting element 11 that that includes sloped portion 12, at least one movement control component such as rails 13 that are coupled to the sloped portion and movable element 14 that is adapted to move along the at least one movement control component. Movable element 14 is adapted to support the imager. When movable element 14 supports the imager a center of gravity of a combination of movable element 14 and the imager is positioned above the sloped portion or in proximity to the sloped portion. An example of such a combination of elements is illustrated in PCT patent application WO 2008/090559 titled “METHOD AND SYSTEM FOR SUPPORTING A MOVING OPTICAL COMPONENT ON A SLOPED PORTION” which is incorporated herein by reference.

Referring back to FIG. 1a—system 10 also includes illustrates first longitudinal transferor 110, first rotation module 210, second longitudinal transferor 120, second rotation module 220, third longitudinal transferor 130, third rotation module 230, fourth longitudinal transferor 140, delay element 150, sorting unit 170 and processor 160.

At least one of the mentioned above longitudinal transferors and preferably all longitudinal transferors 110, 120, 130 and 140 include a movable portion that once moved to a certain position exposes tunnels of these longitudinal transferors and allow these tunnels (as well as other portions of these longitudinal transferors—including the movable portions themselves) to be cleaned.

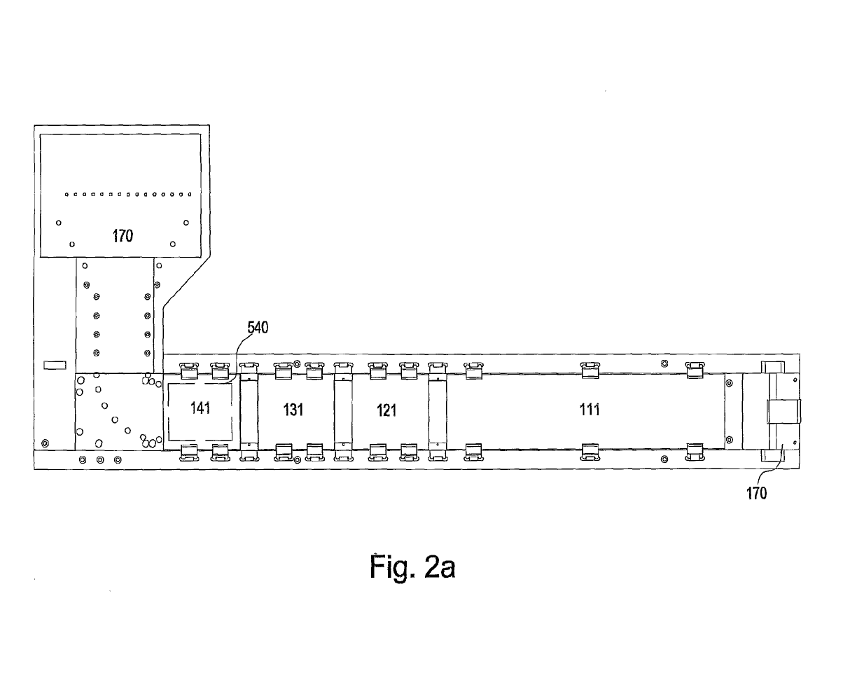

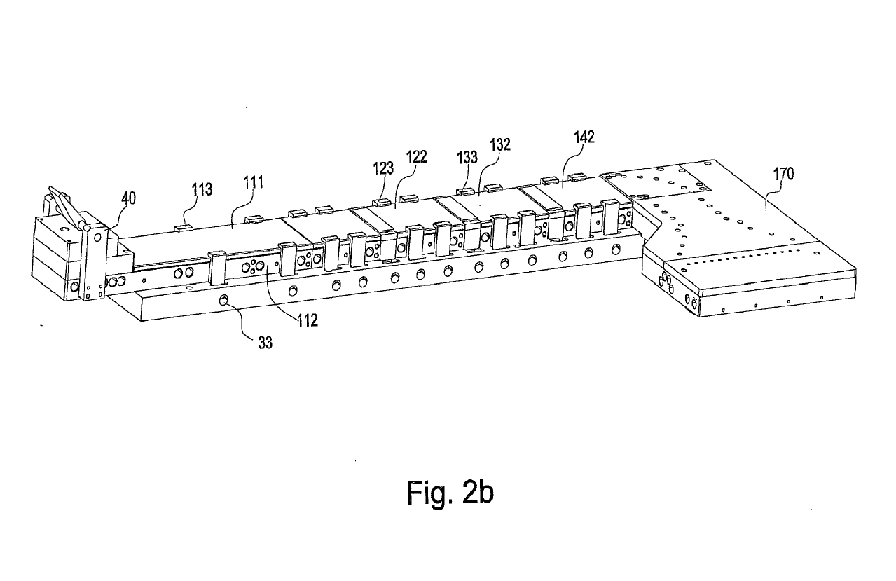

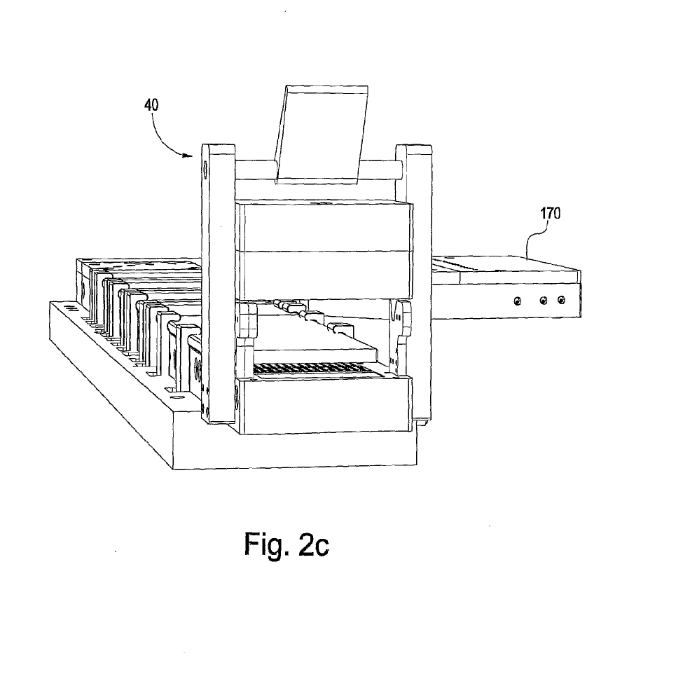

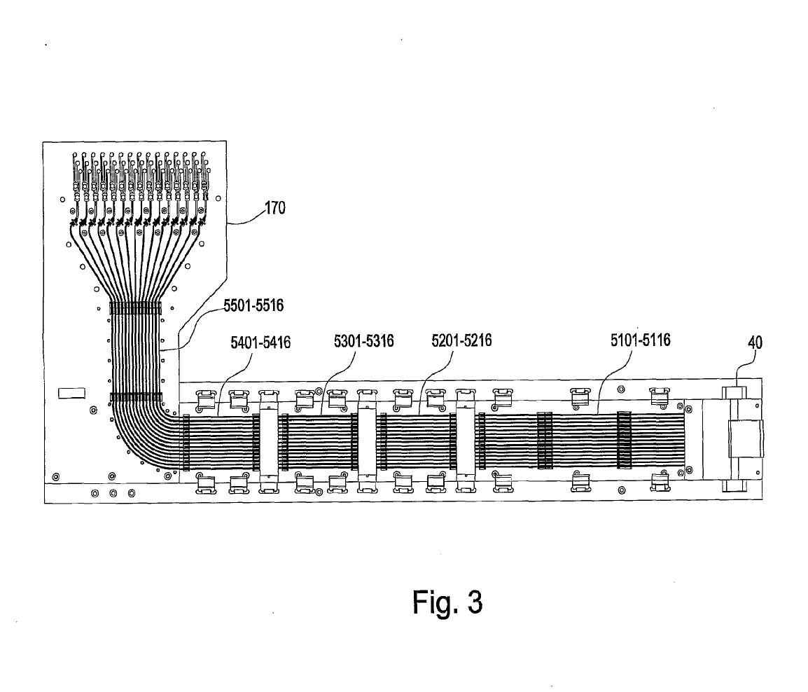

FIGS. 2a, 2b, 2c and 3 illustrate various portions of system 10. FIGS. 2a, 2b, 2c illustrate a portion when removable portions are at a position that allows imaging objects while FIG. 3 illustrates the portion once the movable portion is removed—thus exposing tunnels 5101-5116, 5201-5216, 5301-5316, 5401-5416 and 5501-5516. These tunnels, as well as grooves within rotating elements 210, 220 and 230 form sixteen propagation paths that are substantially parallel to each other—at least till reaching sorting unit 170.

System 10 includes supply element 40, first longitudinal transferor 110, first rotation module 210, second longitudinal transferor 120, second rotation module 220, third longitudinal transferor 130, third rotation module 230, fourth longitudinal transferor 140, delay element 150 and sorting unit 170.

First till first longitudinal transferors 110, 120, 130 and 140 include movable portions such as transparent upper movable portions 111, 121, 131 and 141 respectively that once removed expose the tunnels of these transferors. The tunnels are formed in lower portions 112, 122, 132 and 142 of these longitudinal transferors.

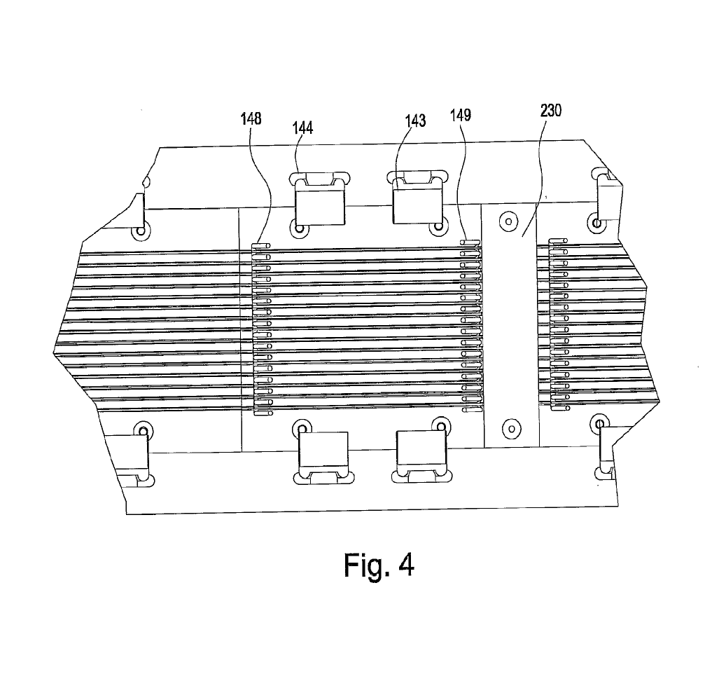

First longitudinal transferor 110 includes lower portion 112 in which tunnels 5101-5116 are formed, transparent upper movable portion 111, stopping elements 148 and 149 (shown in FIG. 4) and gas related elements (illustrated in FIG. 2b as inlets 33). Second longitudinal transferor 120 includes lower portion 122 in which tunnels 5201-5216 are formed, transparent upper movable portion 121 as well gas related elements and stopping elements. Third longitudinal transferor 130 includes lower portion 132 in which tunnels 5301-5316 are formed, transparent upper movable portion 131 as well gas related elements and stopping elements. Fourth longitudinal transferor 140 includes lower portion 142 in which tunnels 5401-5416 are formed, transparent upper movable portion 141 as well gas related elements and stopping elements.

System 10 further includes delay element 150 and sorting unit 170.

Movable portions 111, 121, 131 and 141 are forced against lower portions 112, 122, 132 and 142 by clips 113, 123, 133 and 143. This allows to substantially seal the tunnels of First till first longitudinal transferors 110, 120, 130 and 140 during the imaging process. Clips can move within openings such as openings 114 and 144.

It is noted that the upper portion and the lower portion of each longitudinal transferor can be held together in various other manners known in the art.

Conveniently, system 100 operates in a pipelined manner—groups of elements are moved from imaging area to the other, and images from multiple imaging areas can be obtained during each imaging cycle.

Table 1 illustrates the initialization of a pipelined process by which system 100 operates. “Cycle” indicates an inspection cycle during which a stage occurs. LTS1-LTS4 are the first till fourth longitudinal transferor 110-140, “image” indicate which images are taken, Sx (Gy) means the image of the x′th side of the y′th group of electrical circuits. For simplicity of explanation the rotation module of electrical circuits is not shown.

TABLE-US-00001 Cycle LTS1 Image LTS2 Image LTS3 Image LTS4 Image C1 G1 S1 (G1) C2 G2 S1 (G2) G1 S2 (G1) C3 G3 S1 (G3) G2 S2 (G2) G1 S3 (G1) C4 G4 S1 (G4) G3 S2 (G3) G2 S3 (G2) G1 S4 (G1) C5 G5 S1 (G5) G4 S2 (G4) G3 S3 (G3) G2 S4 (G2) C6 G6 S1 (G6) G5 S2 (G5) G4 S3 (G4) G3 S4 (G3) C7 G7 S1 (G7) G6 S2 (G6) G5 S3 (G5) G4 S4 (G4) C8 G8 S1 (G8) G7 S2 (G7) G6 S3 (G6) G5 S4 (G5) C9 G9 S1 (G9) G8 S2 (G8) G7 S3 (G7) G6 S4 (G6)

FIG. 4 illustrated stopping elements 148 and 149. One located just after third rotation module 230 and the other located at an opposite end of fourth longitudinal transferor 140—towards the tunnels that end at delay unit 150.

These stopping elements can be pins that can be elevated or lowered—when elevated they prevent objects to pass through the tunnels. The top portion of each stopping element is clearly shown in FIG. 4. These stopping elements can be located within a recess that is also shown in FIG. 4.

It is noted that lower portion 112, 122, 132 and 142 can be transparent—allowing to obtain images through the lower portion. Such images can be acquired in parallel to the images acquired by imager 30 located above longitudinal transferors 120 and 130.

Conveniently, system 10 includes topping elements (not shown) that can be located in first, second third and fourth longitudinal transferors 110, 120, 130 and 140, near the first second and third rotation modules 210, 220 and 230 and near delay unit 150. These stopping elements can pop into (or otherwise enter) the tunnels are temporarily prevent the propagation of objects from one module to the other. These stopping elements can be values.

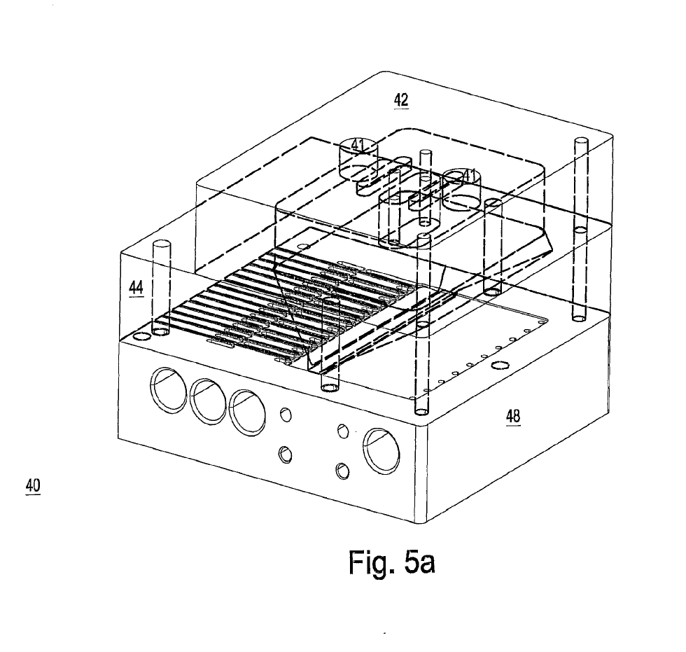

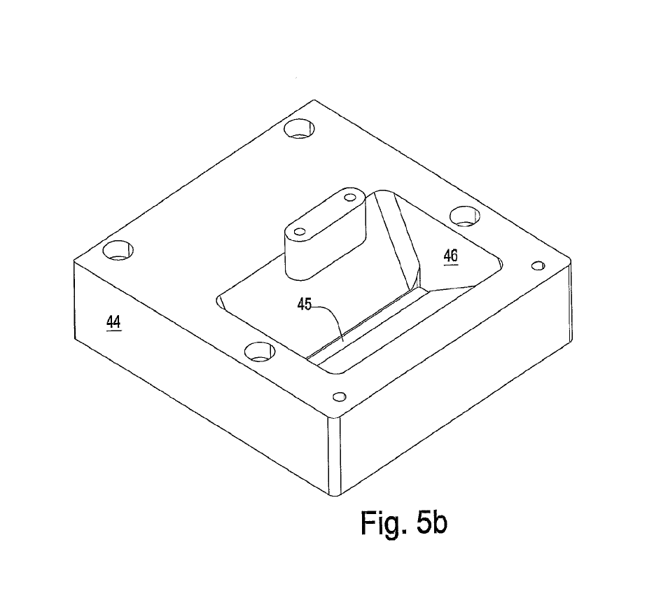

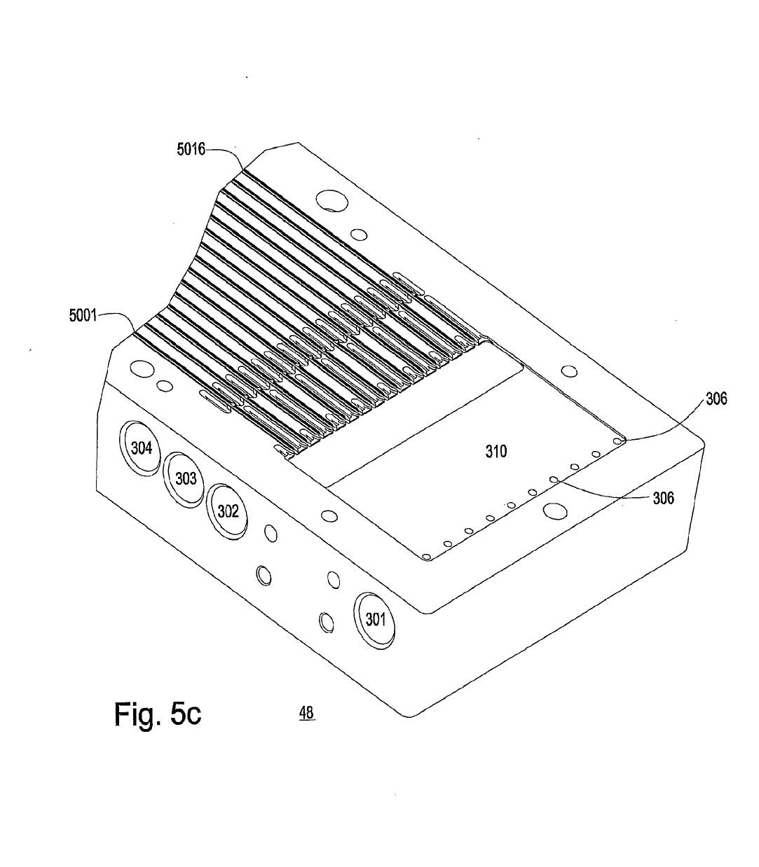

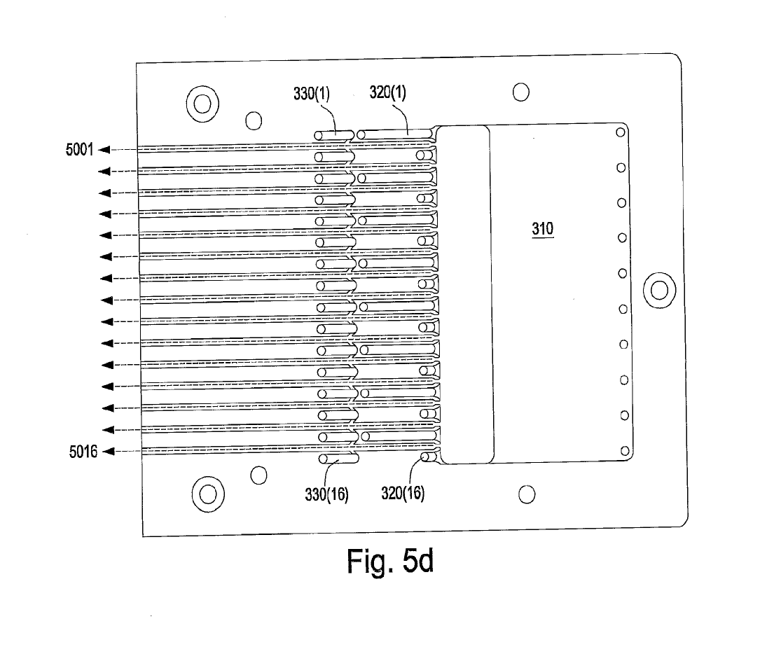

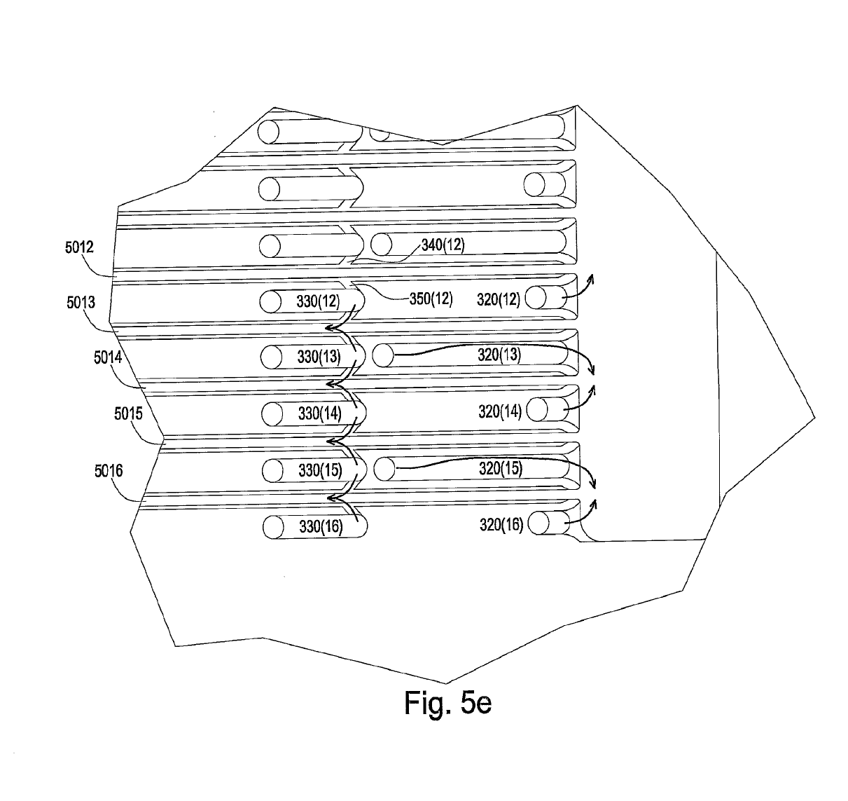

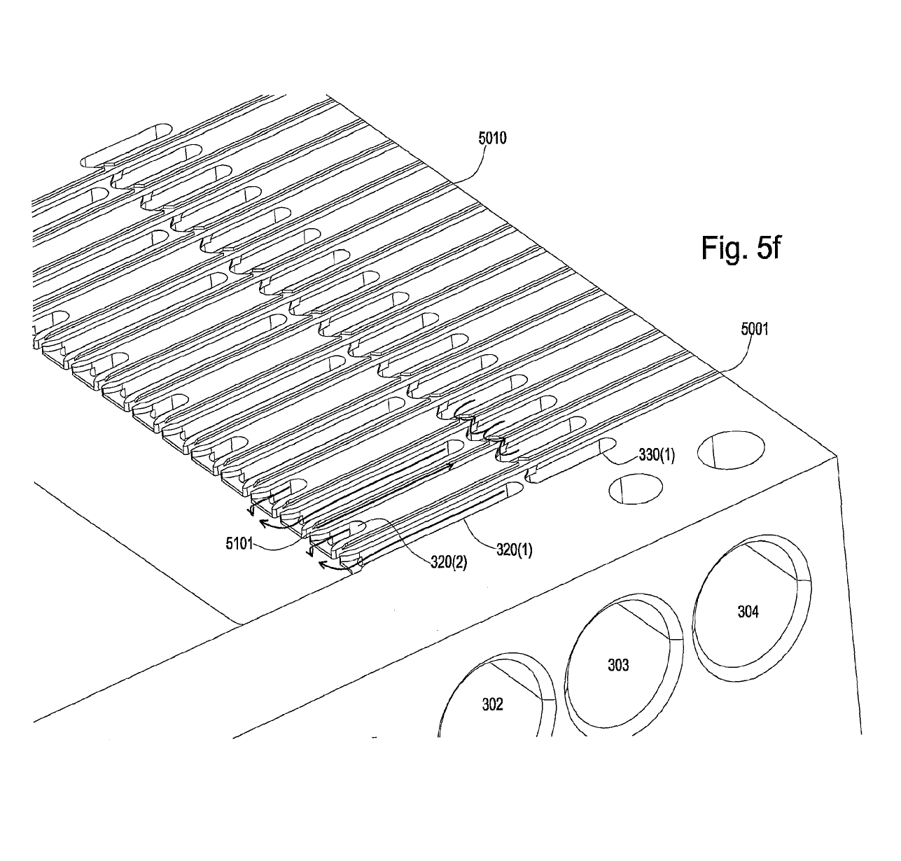

FIGS. 5a-5f illustrate supply element 40 and portions thereof according to an embodiment of the invention.

Objects can be sucked (or otherwise provided) to one or more inlets (such as inlets 41) 41 of supply element 40 and then fall (through beveled inner space 46) via outlet 45 of the supply element towards tunnels of first longitudinal transferor 110.

Supply element 40 has an upper portion 42 that receives the objects, a middle portion 44 that defines a substantially horizontal space such as beveled inner space 46 (that has a long and narrow opening 45) and a bottom portion 48.

The bottom portion includes four horizontal (sub-surface) air conduits 301, 302, 303 and 304. Multiple openings at the upper level of bottom portion 48 can drive air provided through these conduits such as to affect capacitors that fall via opening 45 towards a beveled space 310.

Objects arrive to beveled space 310 that is shaped such as to prevent objects from being stack one above the other. It can be relatively narrow—its height is approximately equal to the height of the objects. Accordingly, in this space objects can not pile on each other (in the vertical dimension).

It is noted that the beveled space can be replaced by a substantially horizontal space that is also relatively narrow.

Objects can be forced to move towards tunnels 5001-5006 by air pulses (or a continuous gas pressure) that arrive via conduit 301 and then through openings 306. This air pulses can be applied when the beveled space 310 is only partially filled or includes only few objects.

Objects that are proximate to the inputs of tunnels 5001-5016 can be induced to move into the tunnel by gas pulses or gas pressure provided vie either one of openings 320(1)-320(16) and 330(1)-330(16).

Openings 320(1)-320(16) are arranged in a staggered manner—the odd openings receive gas via conduit 302 while the even openings receive gas via conduit 303. The gas can be provided in a pulsed manner, a continuous manner or a combination thereof. The gas pulses can be provided simultaneously to conduits 302 and 303, in an overlapping manner or in a non-overlapping manner.

Conduit 304 provides gas (in a pulsed or continuous manner or a combination thereof) via openings 330(1)-330(16). The gas enters tunnels 5001-5016 via openings (such as openings 340(12) and 350(12) that are formed at both sides of tunnel 5012 and are illustrated in FIG. 5e) formed at the sidewalls of the tunnels and can direct objects to exit the tunnels. It can prevent object from returning (via the tunnels) to beveled space 310. They can be used to inject relatively strong gas pulses that assist in cleaning the tunnels.

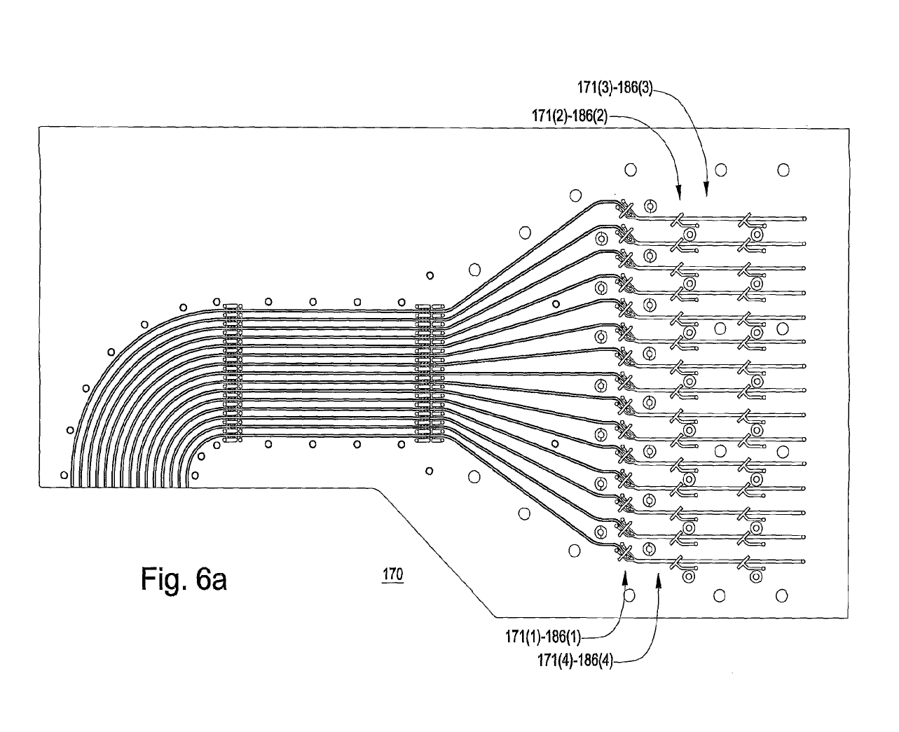

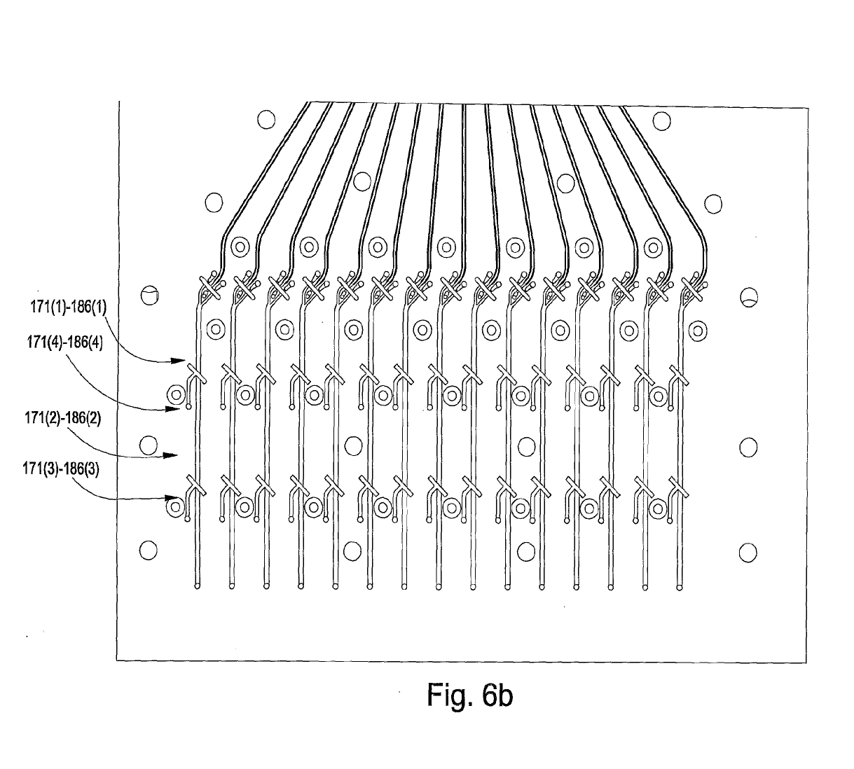

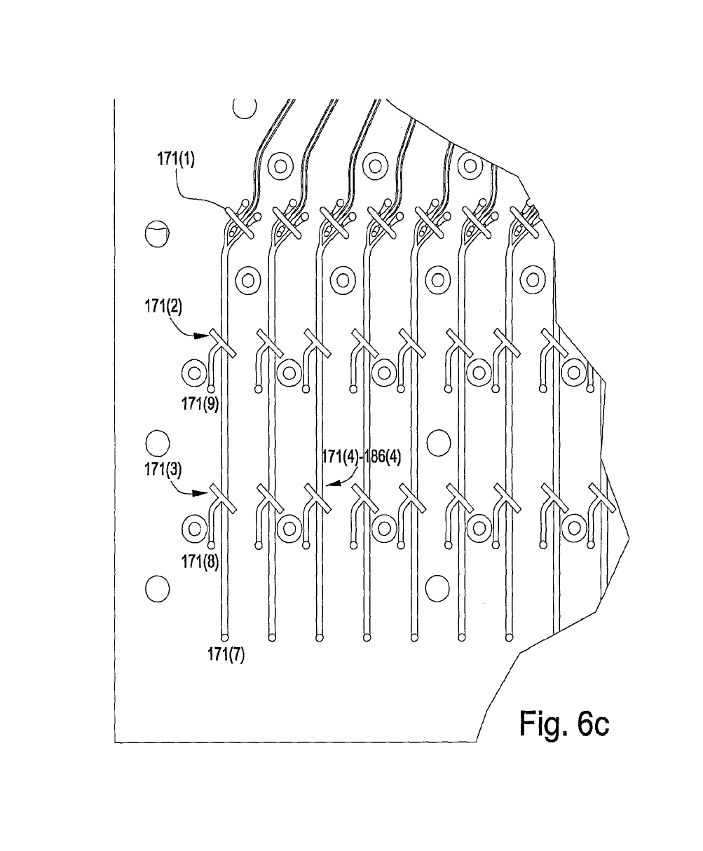

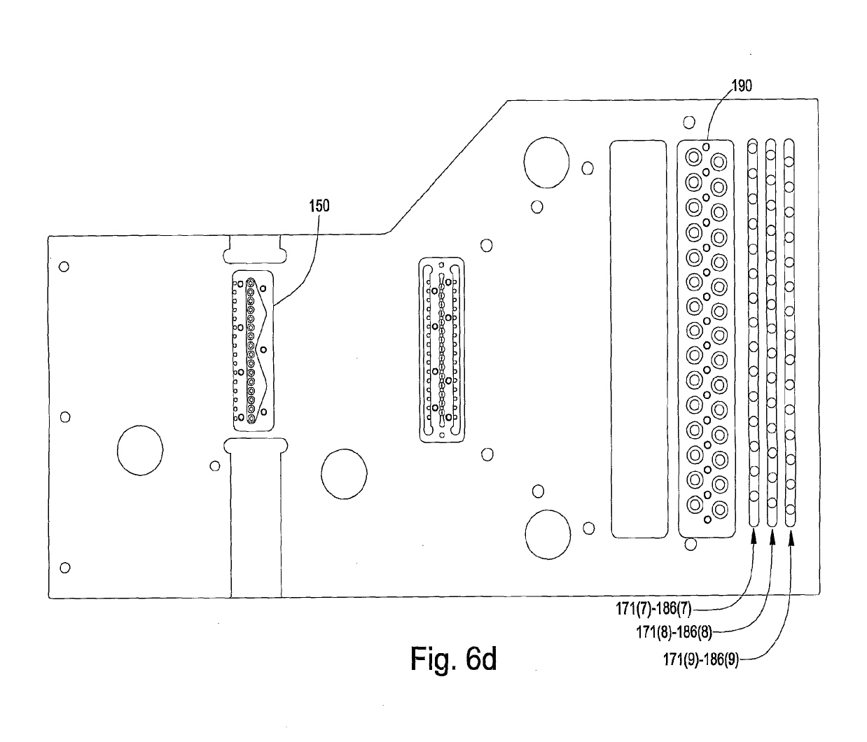

FIGS. 6a-6c illustrate sorting unit 170 according to an embodiment of the invention.

Sorting unit 170 can include a set of sorting element per each channel of fourth longitudinal transferor 140. For example—sixteen tunnels require sixteen sets of sorting elements.

The spacing between the channels of sorting unit 170 is larger than the spacing between the tunnels of the longitudinal transferors 110, 120, 130 and 140. This allows placing multiple sorting elements per each sorting unit channel. The tunnels of the longitudinal transferors 110, 120, 130 and 140 are close to each other in order to reduce the size of the imaging areas.

Sorting unit 170 can include multiple control elements that are movable by gas. An example of a gas driven control element and a sorting unit is illustrated in PCT patent application WO 2007/129322 titled “System and method for imaging objects” which is incorporated herein by reference.

In a nut-shell, each sorting channel includes one inlet, multiple outlets and multiple control elements that assist in directing the electrical element to one of the multiple outlets.

FIGS. 6a and 6b illustrate three groups of control elements—first group includes control elements 171(1)-186(1), second group of control elements includes control elements 171(2)-186(2) and third group of control elements includes control elements 171(3)-186(3). FIG. 6c illustrates few sorting channels.

The first group of control elements 171(1)-186(1) includes sixteen control elements that selectively allow objects to enter the sorting channels—one object per sorting channel at a time. The objects can be electrically tested when they are located at the first group.

The second and third groups of control elements include binary sorting element—each capable of directing an object to one out of two output paths.

All control elements of a group are parallel to each other and are oriented in relation to a longitudinal axis of the tunnel that precedes this control element.

An object can be sorted in few milliseconds but is can be sorted either more quickly or more slowly.

FIG. 6d illustrates the bottom of sorting unit 170 and delay unit 150. It includes two columns of openings 190 for placing second group of control elements includes control elements 171(2)-186(2) and third group of control elements includes control elements 171(3)-186(3) It also include three columns of outlets—a first column that includes output outlets 171(7)-186(7), a second column that includes output outlets 171(8)-186(8), and a third column that includes output outlets 171(9)-186(9).

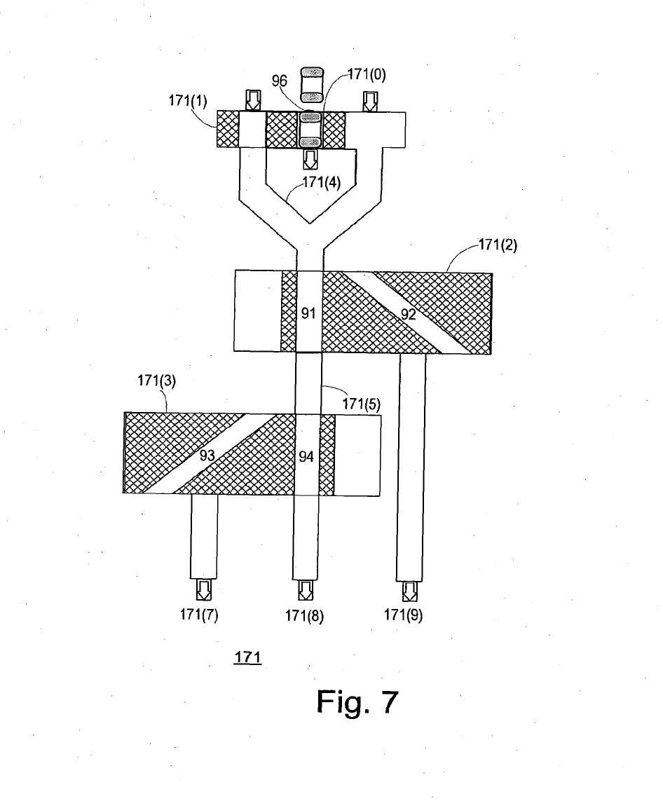

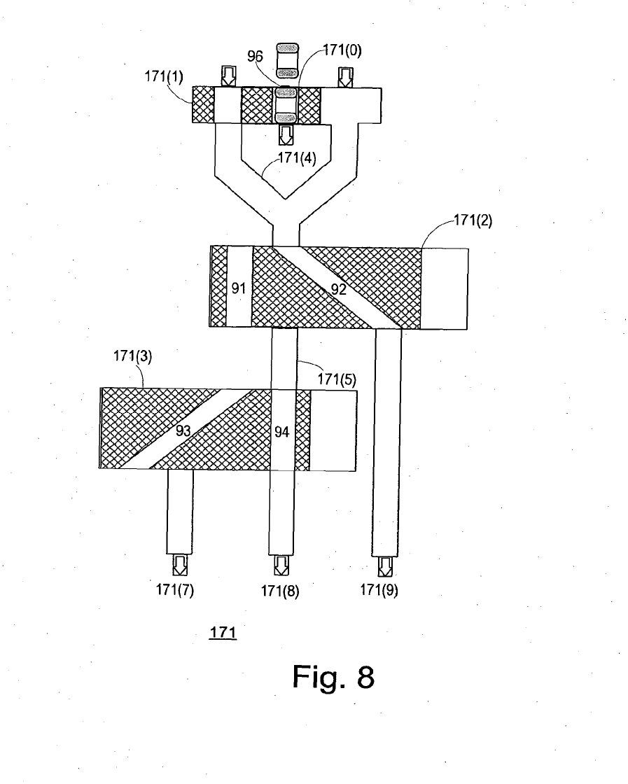

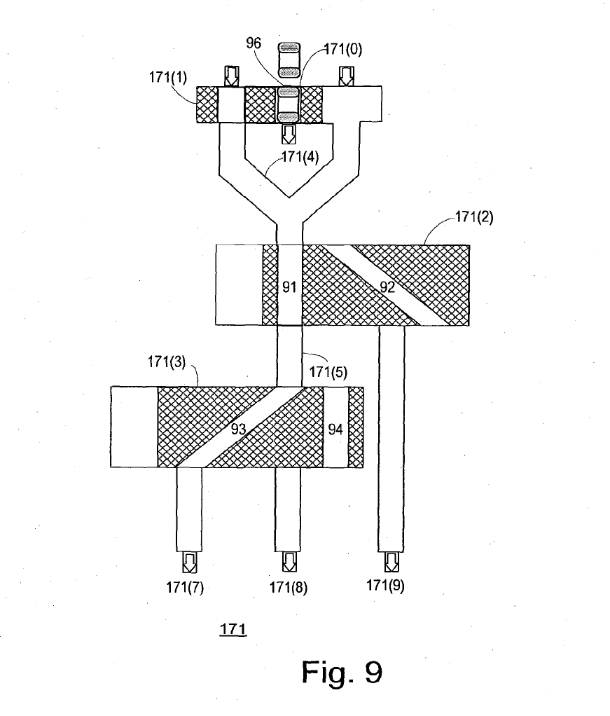

FIGS. 7, 8 and 9 illustrate the positions of three control elements of a single channel 171 of sorting unit 170 when sorting a good object, a bad object and a questionable object.

Channel 171 has an input 171(0) that receives objects from tunnels of delay unit 150.

The first movable element 171(1) has an opening that can include a single object. When it is positioned at a center position it can receive an object. When it is positioned in either one of a rightmost position and a leftmost position it can release that object towards tunnels 171(4). First movable element 171(1) alternates between a rightmost position and a left most position. The rotation is performed in a periodical manner regardless of the functionality of the object. This alternating movement allows a single object to be sent toward control element 171(2) of channel 171. First control element 171(2) includes two tunnels—91 and 92. Second control element 171(3) includes two tunnels—93 and 94. These two directional elements can be moved so that these tunnels receive an object and direct it towards one of the three outlets of channel 171-“questionable” output outlet 171(7), “good” output outlet 171(8) and “bad” output outlet 171(9). The location of these directional elements is determined by processor 160—in view of the functionality of the electrical element that is received by first movable element 171(1).

For example, if the object is “bad” then first control element 171(2) is placed so that tunnel 92 faces tunnel 171(4) and an object that exits tunnel 171(4) is directed towards “bad” output outlet 171(9).

Yet for another example, if the object is “good” or “questionable” then first control element 171(2) is placed so that tunnel 91 faces tunnel 171(4) and an object that exits tunnel 171(4) is directed second control element 171(3). If the object is “good” then second control element 171(3) is placed so that tunnel 93 faces tunnel 91 and an object that exits tunnel 91 is directed towards “good” output outlet 171(8). If the object is “questionable” then second control element 171(3) is placed so that tunnel 94 faces tunnel 91 and an object that exits tunnel 91 is directed towards “questionable” output outlet 171(7).

Conveniently, an object that is received by first movable element 171(1) is electrically tested—using electrical connections that contact the object. This can require placing first movable element 171(1) in a position that differs from its central position, rightmost position and leftmost position. This position can be between the center position and any out of the rightmost and leftmost positions. This can require two sets of electrodes—one per each intermediate position.

FIG. 7 also illustrates a pair of electrodes 96 that are positioned so as to contact an object when placed at the central position. It is noted that electrodes can be positioned to contact the object when it is placed at a right intermediate position and when placed at a left intermediate position.

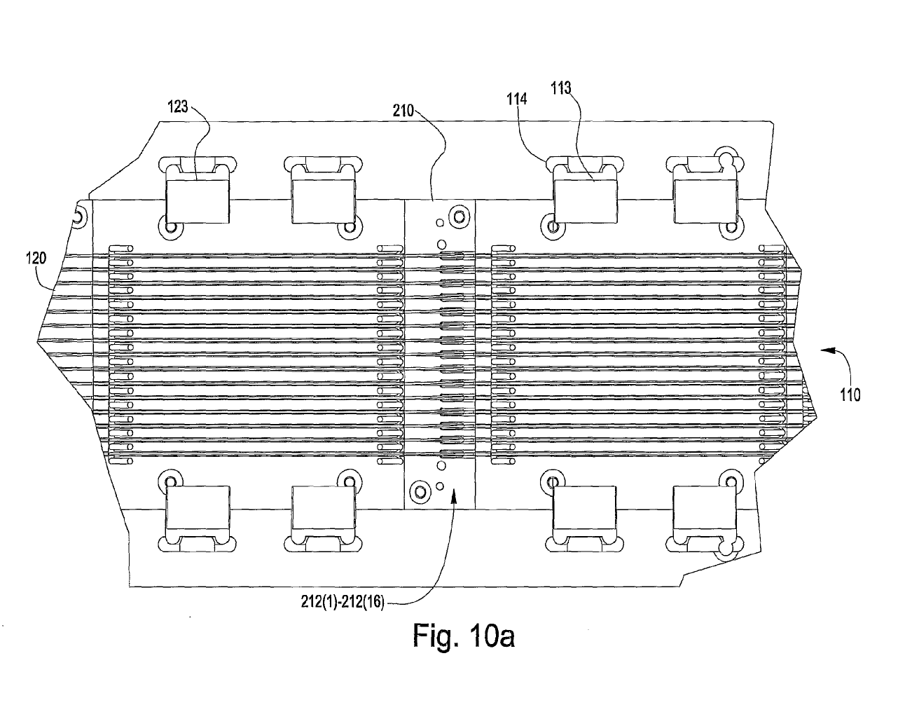

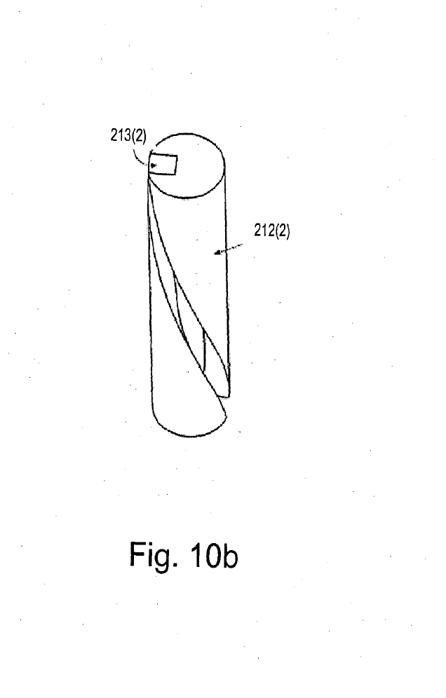

FIG. 10a illustrates rotation elements 212(1)-212(16) of first rotation module 210 and portions of first and second longitudinal transferors 110 and 120 various tunnels according to an embodiment of the invention.

Rotation module 210 includes sixteen rotation elements 212(1)-212(16)—one per each tunnel of first longitudinal transferor 210. Tunnel 5101 is connected via first rotation element 212(1) to tunnel 5201. Tunnel 5201 is connected via second rotation element 212(2) to tunnel 5202 and so fourth—till tunnel 5116 that is connected via rotation element 212(16) to tunnel 5216.

FIG. 10b illustrates rotation element 212(1) according to an embodiment of the invention.

Rotation element 212(1) includes a spiral groove 213(1) that performs a rotation of about ninety degrees. Objects from a tunnel of first longitudinal transferor 110 enter one end of spiral grove, and are rotated at about ninety degrees about their longitudinal axis before exiting the spiral groove 213(2) to enter a corresponding tunnel of second longitudinal transferor 120.

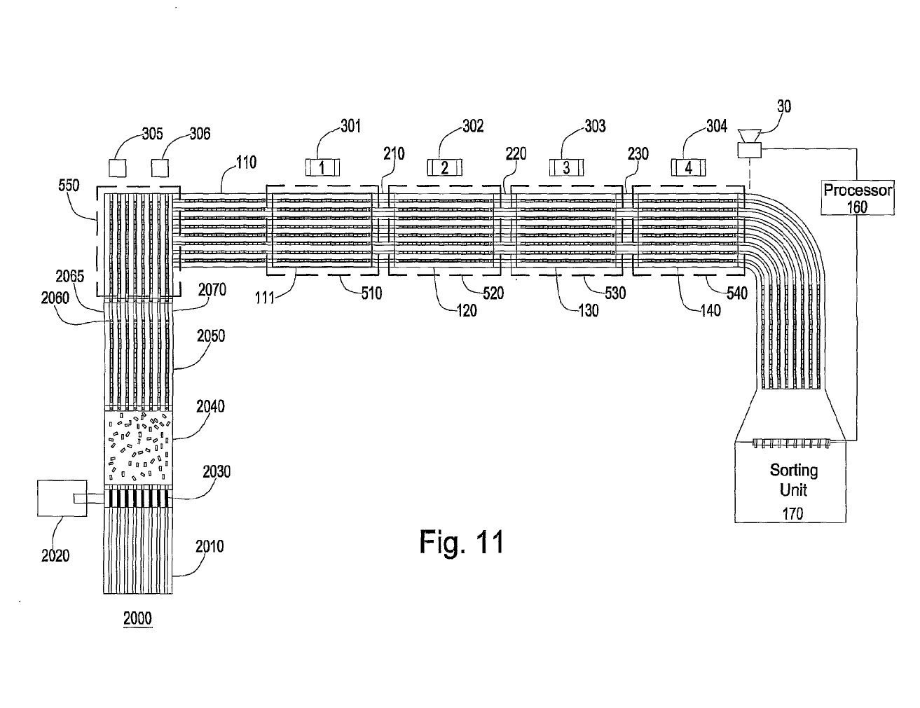

FIG. 11 illustrates system 10 according to another embodiment of the invention.

System 10 of FIG. 11 includes lateral transferor 310 that is adapted to transfer the objects to an additional imaging area 250 in a lateral manner. Imager 30 is configured to obtain images of two opposite sides of the objects that differ from sides of the objects that are imaged at the four imaging areas 510, 520, 530 and 540.

Conveniently, the additional imaging area includes illuminating sloped mirrors positioned so that the objects are positioned between the sloped mirrors. Light scattered or reflected from opposite sides of the objects are directed from these sloped mirrors towards the imager.

System 2000 includes various push-pull stripes called buses 2010; a motor 2020; multi-clutch 2030; container 2040; bus platform 2050; load element such as load bus 2060; additional imaging area 550; bus un-loader 2065; first longitudinal transferor 110; first rotation element 210, second longitudinal transferor 120, second rotation element 220, third longitudinal transferor 130, third rotation element 230, fourth longitudinal transferor 140, delay unit 150; processor 160 and sorting unit 170.

Buses push—pull stripes 2010 are multiple lateral transferor elements that form a lateral transferor that moves electrical objects to the right (to be imaged) and then to the left (after being imaged) and the push-pull stripes push move these buses to the left and to the right.

Bus motor 2020 and multi-clutch 2030 move the stripes 2010 to the left and to the right and the multi-clutch 2030 converts the mechanical movement of bus motor 2020 to left and right movements. Container 2040 included the electrical objects. Bus platform 2050 includes multiple buses—each bus has a long base and a sequence of evenly spaced projections whereas each pair of adjacent projections defined a space that can support a single electrical object. Load bus 2060 loads the electrical objects to the buses so that their longitudinal axis is normal to the transferring axis of the buses. Bus un-loader 2065 unloads the electrical objects after they were imaged by imager 30 to be rotated (by 90 degrees) and are transferred (conveniently below the first imaging area) to first longitudinal transferor 110.

Objects are provided to additional imaging area 550 and then return to their position before this imaging to be unloads and provided (conveniently under the buses) to first longitudinal conveyor 110.

Two different sides of the objects are obtained at different imaging areas. For example—assuming that the six sides are referred to as sides A, B, C, D, E, and F then sides A and C are imaged at the first imaging area, sides B and D are imaged at the second imaging area and sides E and F are imaged at the third imaging area. These images are illustrated by boxes 305 and 306 while the images obtained in the other four imaging areas 510-540 are illustrated by boxes 301-302, 303 and 304.

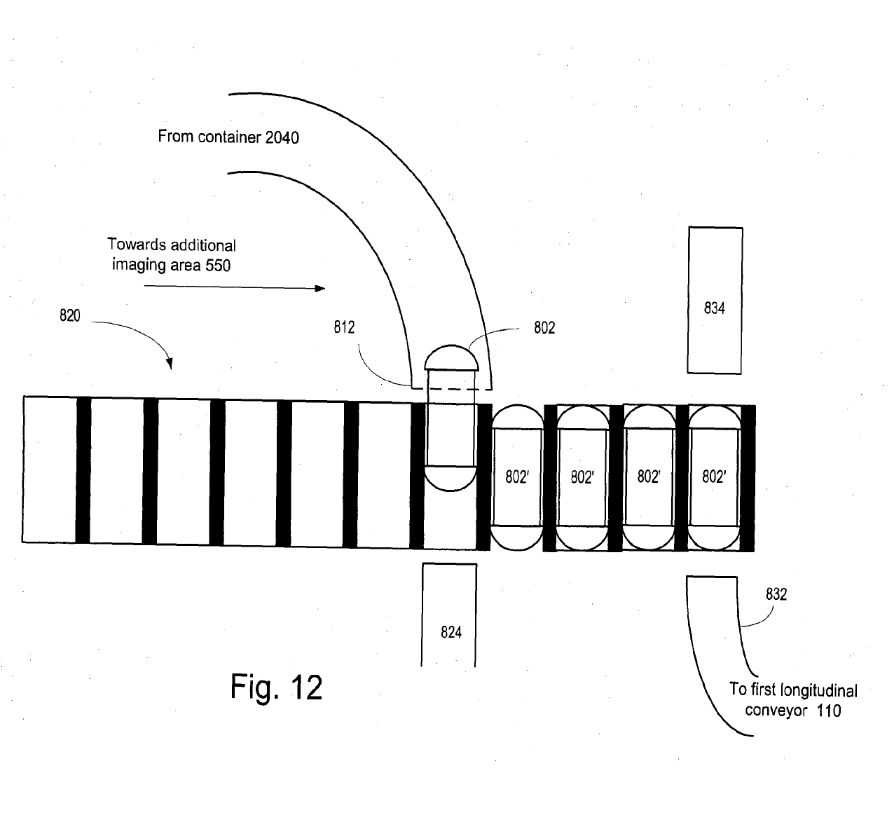

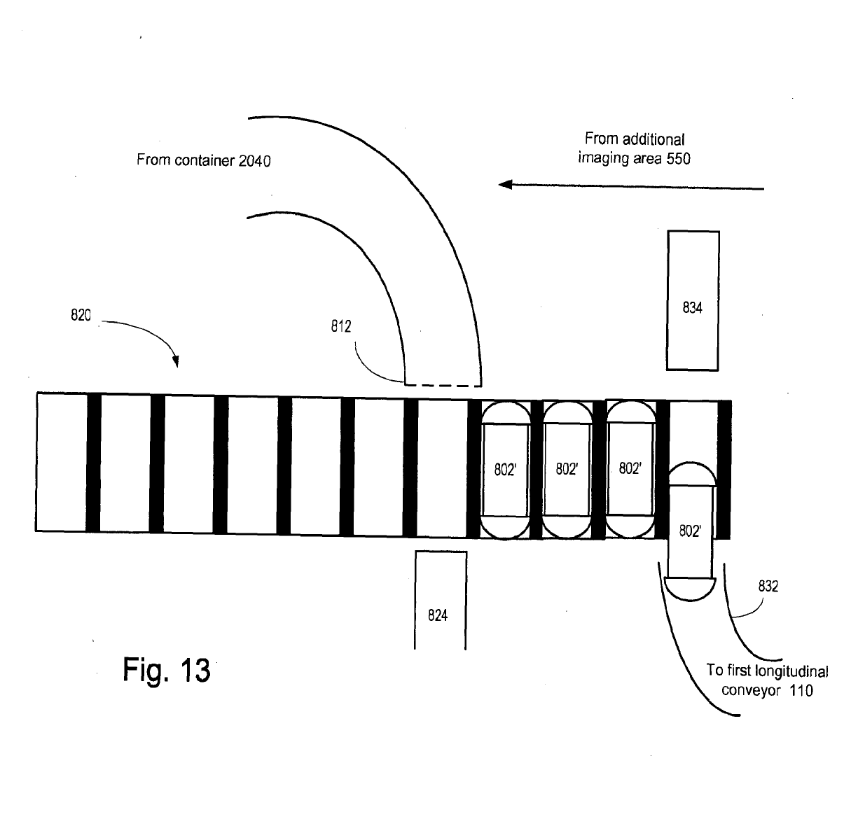

FIGS. 12 and 13 illustrate a bus 820, loading elements of loader 2060 and unloading elements of un-loader 2065 according to an embodiment of the invention.

It is assumed that additional imaging area 550 is located at the right of bus 820.

FIG. 12 illustrates loading elements 812 and 824 that load objects to bus before the imaging takes place and bus 820 (loaded within objects such as objects 802′) moves to the right. After the imaging is completed bus 820 returns to its initial position (moved to the left—as illustrated in FIG. 13) and unloading elements 832 and 834 unload the imaged objects from bus 820.

Loading element 812 is a tunnel that starts near container 2040 and loading element 824 sucks the elements (by introducing a low gas pressure) towards bus 820.

Un-loading element 832 is a tunnel that extends (preferably below bus 820) towards first longitudinal transferor 110. Loading element 834 generates gas pulses that push the objects from bus 820 towards un-loading element 832.

Bus 820 conveys the objects so that their longitudinal axis is substantially orthogonal to the movement of the bus.

Bus 820 or other transferring element can be a part of a conveyor belt, can include multiple partitions, or can be moved towards additional imaging area 550 by mechanical, magnetic or gas pressure based means.

According to another embodiment of the invention, loading and unloading elements can operate in parallel—to remove already imaged objects from bus while loading objects to be imaged.

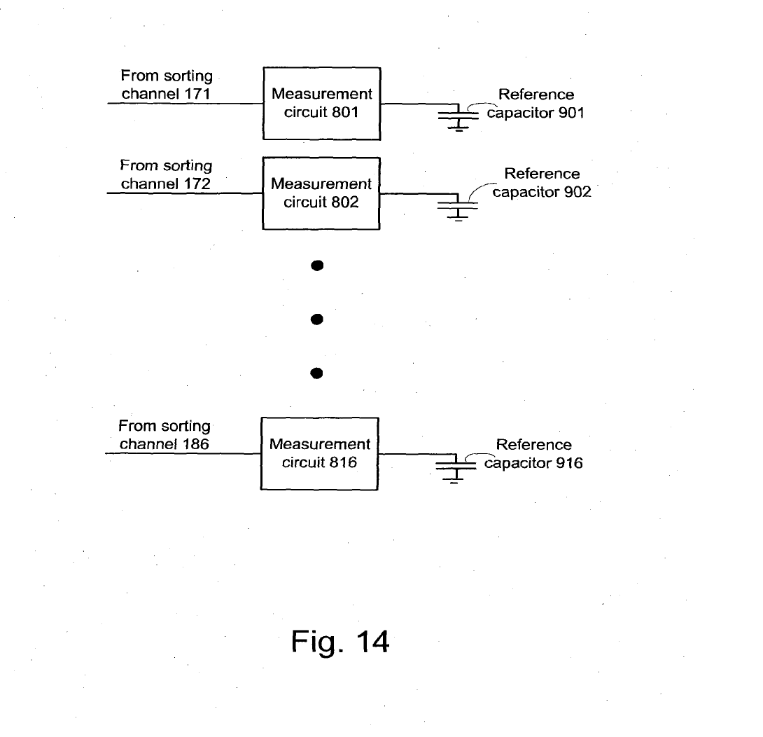

FIG. 14 illustrates an electrical tester 180 according to an embodiment of the invention.

Electrical tester 160 include sixteen measurement circuits 801-816 that are connected to sixteen reference capacitors 901-916 on one hand and to test points (electrodes) of sixteen sorting channels 171-186 of sorting unit 170.

Measurement circuits 801-816 can include capacitance comparators such as PS021 of ACAM mass electronics. They compare very quickly between the capacitance of imaged capacitors (of sorting channels) and the reference capacitors 901-916. The comparison can indicate deviations from required capacitance.

Reference capacitors 901-916 should be kept at substantially the same conditions (temperature, humidity) as the imaged capacitors—so that the comparison is as accurate as possible. Placing the reference capacitors in close proximity to sorting unit 170 can assist in obtaining this goal.

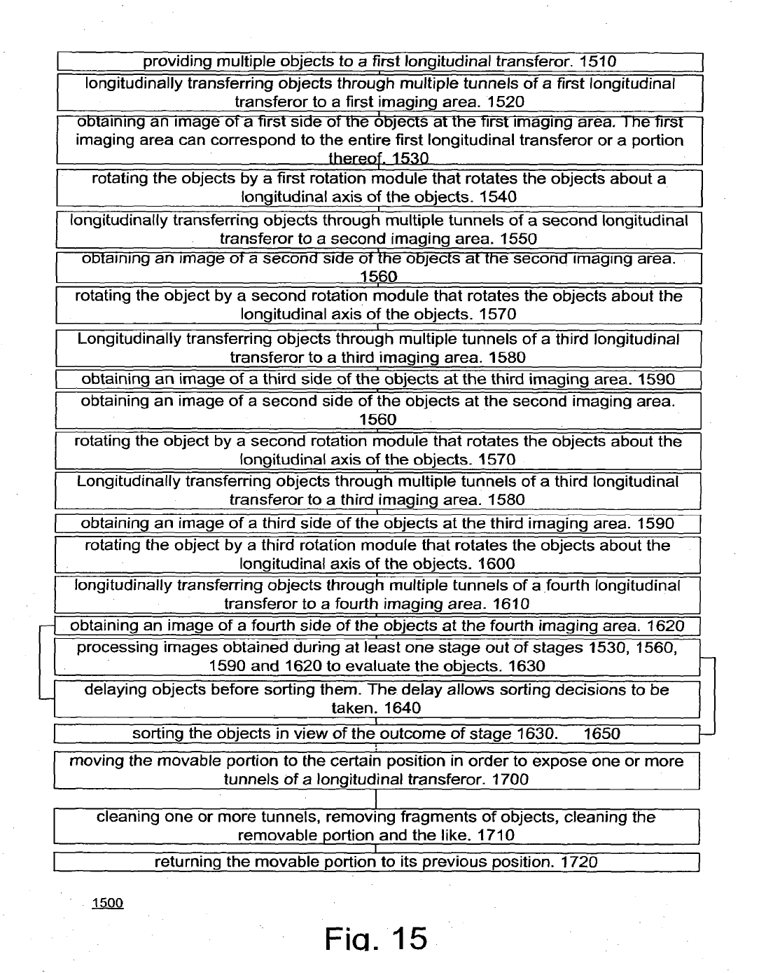

FIG. 15 illustrates method 1500 according to an embodiment of the invention.

Method 1500 starts by stage 1510 of providing multiple objects to a first longitudinal transferor.

These objects can be sucked (or otherwise provided) to an inlet of a supply element and allowing the objects to fall through an outlet of the supply element towards tunnels of the first longitudinal transferor. The supply

Stage 1510 is followed by stage 1520 of longitudinally transferring objects through multiple tunnels of a first longitudinal transferor to a first imaging area. Conveniently, once enough objects are gathered stage 1520 can be followed by stage 1530.

Stage 1520 can include positioning stopping elements of the first longitudinal transferor at a stopping position so that they prevent objects to be sent to the first rotation module. This positioning is followed by sucking the objects so that they form a column of objects per tunnel. The positioning can include moving these stopping elements into the tunnels of the first longitudinal transferor.

Stage 1530 includes obtaining an image of a first side of the objects at the first imaging area. The first imaging area can correspond to the entire first longitudinal transferor or a portion thereof. Accordingly, all or only some of the objects located within the longitudinal transferor can be imaged.

Stage 1530 includes imaging one side of the electrical objects. It can include obtaining the image via a transparent portion of the first longitudinal transferor.

Stage 1530 is followed by stage 1540 of rotating the objects by a first rotation module that rotates the objects about a longitudinal axis of the objects.

Stage 1540 can include rotating the objects by ninety degrees but this is not necessarily so. The rotation can involve rotating by less than ninety degrees, more then ninety degrees and the like.

Stage 1540 can be preceded by changing the position of the stopping elements of the first longitudinal transferor to enable the objects that were imaged in the first imaging area to move to the first rotation module. This re-positioning can include removing these stopping elements from the tunnels of the first longitudinal transferor.

Stage 1540 is followed by stage 1550 of longitudinally transferring objects through multiple tunnels of a second longitudinal transferor to a second imaging area.

Stage 1540 can include positioning stopping elements of the second longitudinal transferor at a stopping position so that they prevent objects to be sent to the second rotation module. This positioning is followed by sucking the objects so that they form a column of objects per tunnel. The positioning can include moving these stopping elements into the tunnels of the second longitudinal transferor. Typically, the stopping elements are placed at a stopping position before the objects are allowed to be sent from the first longitudinal transferor.

Stage 1550 is followed by stage 1560 of obtaining an image of a second side of the objects at the second imaging area.

Stage 1560 is followed by stage 1570 of rotating the object by a second rotation module that rotates the objects about the longitudinal axis of the objects.

Stage 1560 can be preceded by changing the position of the stopping elements of the second longitudinal transferor to enable the objects that were imaged in the second imaging area to move to the second rotation module. This re-positioning can include removing these stopping elements from the tunnels of the second longitudinal transferor.

Stage 1570 is followed by stage 1580 of longitudinally transferring objects through multiple tunnels of a third longitudinal transferor to a third imaging area.

Stage 1580 can include positioning stopping elements of the third longitudinal transferor at a stopping position so that they prevent objects to be sent to the third rotation module. This positioning is followed by sucking the objects so that they form a column of objects per tunnel. The positioning can include moving these stopping elements into the tunnels of the third longitudinal transferor.

Stage 1580 is followed by stage 1590 of obtaining an image of a third side of the objects at the third imaging area.

Stage 1590 is followed by stage 1600 of rotating the object by a third rotation module that rotates the objects about the longitudinal axis of the objects.

Stage 1540 can be preceded by changing the position of the stopping elements of the third longitudinal transferor to enable the objects that were imaged in the third imaging area to move to the third rotation module. This re-positioning can include removing these stopping elements from the tunnels of the third longitudinal transferor.

Stage 1600 is followed by stage 1610 of longitudinally transferring objects through multiple tunnels of a fourth longitudinal transferor to a fourth imaging area.

Stage 1610 can include positioning stopping elements of the fourth longitudinal transferor at a stopping position so that they prevent objects to be sent to the fourth rotation module. This positioning is followed by sucking the objects so that they form a column of objects per tunnel. The positioning can include moving these stopping elements into the tunnels of the fourth longitudinal transferor.

Stage 1610 is followed by stage 1620 of obtaining an image of a fourth side of the objects at the fourth imaging area.

Stage 1620 is followed by stages 1630 and 1640. Stage 1630 includes processing images obtained during at least one stage out of stages 1540, 1570 and 1620 to evaluate the objects. Stage 1630 can include searching for visible defects, searching from deviations from expected size or shape, and the like. Stage 1630 can include determining the functionality of the objects and especially classifying them to functionality classes such as but not limited to “functional”, “defective” or “questionable functionality”. This classification will determine how these objects will be sorted.

Stage 1640 includes delaying objects before sorting them. The delay allows sorting decisions to be taken.

Stages 1640 and 1630 are followed by stage 1650 of sorting the objects in view of the outcome of stage 1630.

At least one longitudinal transferor has a movable portion that when placed in a certain position exposes at least a substantial portion of at least one tunnel.

Conveniently, each of stages 1520, 1540, 1550, 1570, 1580 and 1610 utilizes gas pressure differentials to transfer the objects.

Conveniently, each of stages 1520, 1540, 1550, 1570, 1580 and 1610 includes laterally transferring objects through multiple tunnels, each including substantially vertical sidewalls.

Conveniently, stages 1520, 1540, 1550, 1570, 1580 and 1610 include transferring objects through multiple tunnels of the four longitudinal transferor that form four imaging areas and each of the four longitudinal transferor is much longer than each rotation module.

Conveniently, each of stages 1530, 1560, 1590 and 1620 includes obtaining an image of a single side of the objects and these stages do not include utilizing sloped mirrors or other optical elements that can assist in projecting more than a single side view per object towards an imager.

Gas differentials can introduced in a pulsed manner and in multiple places simultaneously. Typically, the mentioned above stages are executed in a pipelined manner—to enable an acquisition of images of multiple groups of electrical circuits that are located at different imaging areas. These gas pulses can be applied in synchronization with the movement of stopping elements.

Either one of stages can include imaging the objects via a transparent portion (either movable or not) of the longitudinal transferor.

Conveniently, the mentioned above stage are executed in a pipelined manner. For example, while one group of objects is imaged at the first imaging area yet another group of objects is images at another imaging area. These groups of objects should be (once the imaging is completed) move to a next imaging area while the fourth group is send to a delay unit or to a sorting unit. This requires moving the group that is positioned at later stages of the system before another group of objects can take its place. Conveniently this achieved by maintaining time differences between the positioning of stopping elements of different longitudinal transferors. For example, method 1500 can include the following sequence of stages: (i) placing the stopping elements of the fourth longitudinal transferor in a non-stopping position and allowing electrical elements to be sucked towards a delay unit or a sorting unit; (ii) placing the stopping elements of the fourth longitudinal transferor in a stopping position and placing the stopping elements of the third longitudinal transferor in a non-stopping position and allowing electrical elements to be sucked from the third imaging area to the fourth imaging area; (iii) placing the stopping elements of the third longitudinal transferor in a stopping position and placing the stopping elements of the second longitudinal transferor in a non-stopping position and allowing electrical elements to be sucked from the second imaging area to the third imaging area; (iv) placing the stopping elements of the second longitudinal transferor in a stopping position and placing the stopping elements of the first longitudinal transferor in a non-stopping position and allowing electrical elements to be sucked from the first imaging area to the second imaging area; and (v) placing the stopping elements of the first longitudinal transferor in a stopping position and allowing electrical elements to be sucked from the second imaging area to the first imaging area.

After one or more (usually many more) iterations of stages 1510-1620, and additionally or alternatively after a predefined event occurs (for example—one or more tunnels are stuck, one or more tunnels are too dirty) method 150 proceeds to cleaning the tunnels and removing objects or object fragments from the tunnels.

Accordingly, stage 1620 is followed by stage 1700 of moving the movable portion to the certain position in order to expose one or more tunnels of a longitudinal transferor.

Stage 1700 can include removing a movable portion that is detachably connected to other portions of one or more longitudinal transferor or moving the movable portion without detaching it. The latter movement can include sliding, rotating, folding and the like.

Stage 1700 is followed by stage 1710 of cleaning one or more tunnels, removing fragments of objects, cleaning the removable portion and the like. The cleaning can be assisted by vacuum but this is not necessarily so.

Stage 1710 is followed by stage 1720 of returning the movable portion to its previous position. Stage 1720 can be followed by stage 1010.

Transferring the objects during stages such as 1520 can require vacuum and the tunnels should be substantially sealed. Accordingly, movable portion should be returned to its previous position in a manner that facilitates additional iterations of stages 1520-1630. This can be achieved by pressing movable portions against other portions of the system, using elastic members or other sealing elements and the like.

Conveniently, the movable portion is rigid and it is tightened to other portions of the systems by clips.

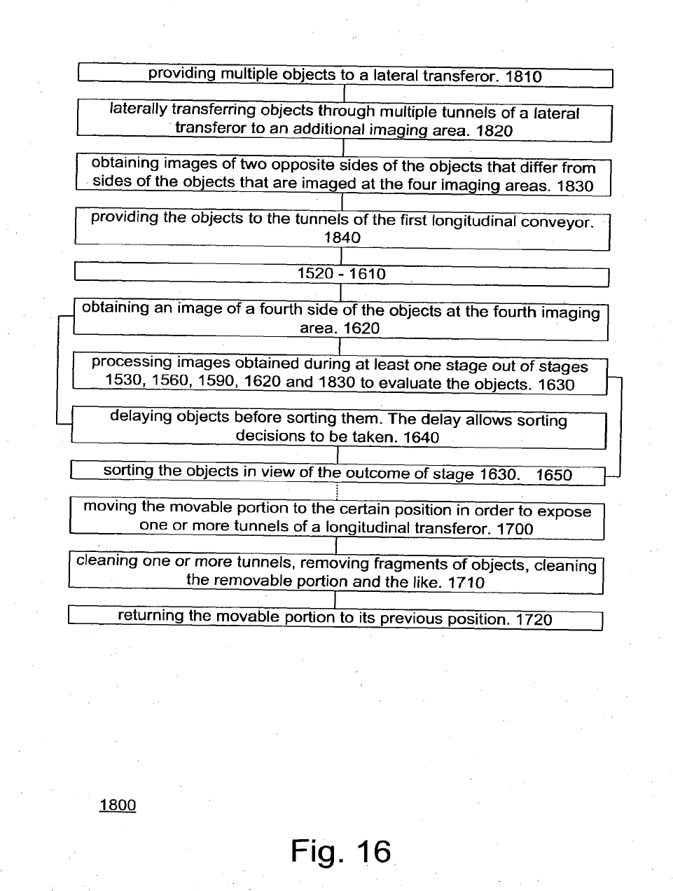

FIG. 16 illustrates method 1800 according to an embodiment of the invention. Method 1800 allows to image six sides of the objects. In addition to stages 1620-1730 of method 1600 it includes stages 1810, 1820, 1830, 1840 and 1850.

FIG. 16 illustrates stages 1810-1850 as preceding stage 1620 but this is not necessarily so.

Stage 1810 includes providing multiple objects to a lateral transferor. This can include allowing electrical objects to propagate along multiple tunnels in a longitudinal manner and sucking then out of these tunnels from an inlet formed at the side of the tunnels to provide them to lateral transferors. This can involve placing these objects on buses that have regularly spaced trajectories that separate one object from another.

Examples of such lateral transferors are illustrated in PCT patent application WO 2007/129322 titled “System and method for imaging objects” which is incorporated herein by reference.

Stage 1810 is followed by stage 1820 of laterally transferring objects through multiple tunnels of a lateral transferor to an additional imaging area. This can be achieved by a bus that receives one object after the other until it positions the electrical circuits at another imaging area.

Stage 1820 can include laterally transferring the objects between pairs of sloped mirrors that allow imaging two opposite sides of the objects.

Stage 1820 is followed by stage 1830 of obtaining images of two opposite sides of the objects that differ from sides of the objects that are imaged at the four imaging areas.

Conveniently, stage 1830 includes at least one of the following or a combination thereof: (i) illuminating at least one pair of sloped mirrors adapted to direct light towards opposite sides of the objects and to direct light reflected or scattered from the opposite sides of the objects towards the imager; (ii) illuminating objects from multiple angles; (iii) illuminating the objects in multiple illumination manners, wherein the different manners can include different wavelength, different polarization, different intensity, and the like; (iv) illuminating a pair of sloped mirrors per each longitudinal transferor, wherein the pair of sloped mirrors is adapted to direct light towards opposite sides of the objects and to direct light reflected or scattered from the opposite sides of the objects towards an imager; (vi) illuminating multiple sloped mirrors that are oriented in forty five degrees.

Stage 1830 is followed by stage 1840 of providing the objects to the tunnels of the first longitudinal conveyor.

Stage 1840 can include moving the bus to its initial position while electrical objects are forced to propagate towards tunnels of the first longitudinal transferor.

It is noted that stage 1630 can also be responsive to images obtained during stage 1830.

It is further noted that method 1800 can include moving at least one movable portion of the lateral transferor to expose at least one tunnel of the lateral transferor so that this tunnel can be cleaned.

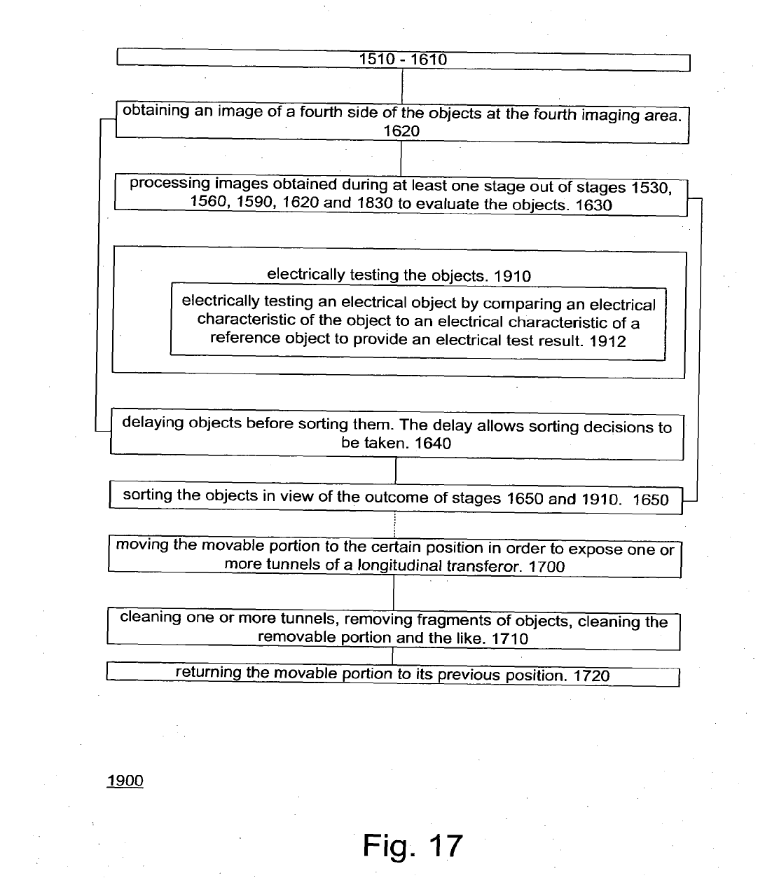

FIG. 17 illustrates method 1900 according to an embodiment of the invention. Method 1900 includes stages 1610-1730 of method 1600 but also includes stage 1910 of electrically testing the objects. Stage 1910 should precede stage 1630. It can follow stage 1620 but this is not necessarily so.

Stage 1630 can be responsive to the results of these electrical testing.

Stage 1910 includes stage 1912 of electrically testing an electrical object by comparing an electrical characteristic of the object to an electrical characteristic of a reference object to provide an electrical test result.

If the objects are capacitors then stage 1910 can include comparing a capacitance of a capacitor to a capacitance of a reference capacitor. This comparison can be executed in a very short time—especially in comparison to absolute capacity measurements.

It is noted that stage 1910 can be included in method 1800.

It is also noted that the electrical testing can be executed only to some of the objects—based upon their functionality. Thus, if the image analysis indicates that an object is faulty the electrical testing can be skipped. Yet for another example—an object can be classified as functional only after both image processing and electrical tests indicate that it is functional.

Stage 1910 can be executed by utilizing electrical test points located in a system that generated the images. These electrical testing points can be located within the lateral transferor, within a longitudinal transferor, within a sorting unit, within a rotation module and the like. The location of these test points determines the relative order of the electrical testing and the image acquisition stages.

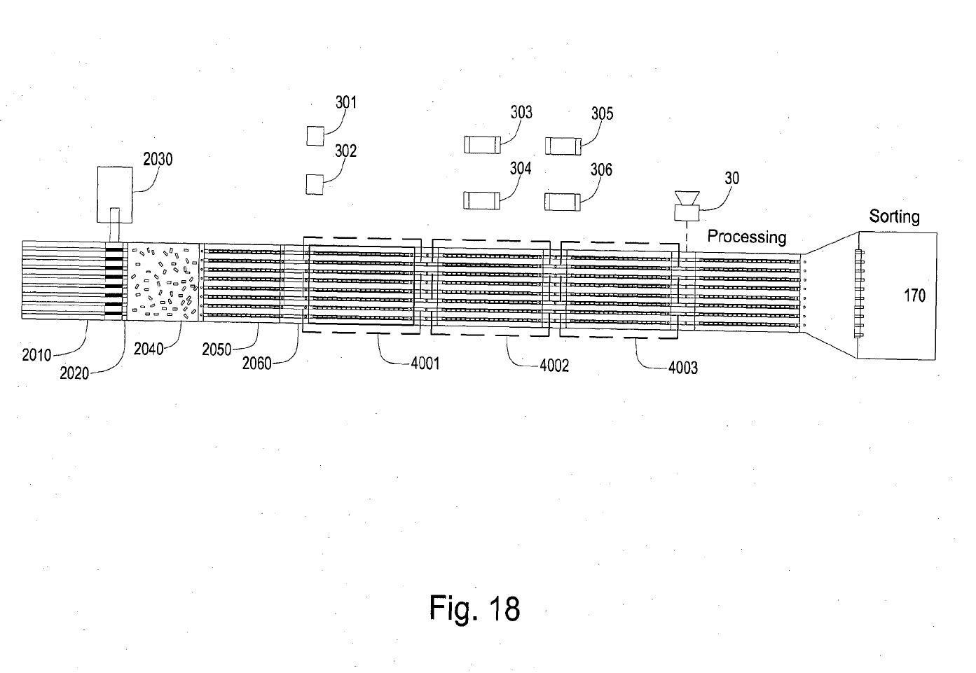

FIG. 18 illustrates system 2000 according to an embodiment of the invention.

System 2000 includes (from left to right): (i) buses push-pull stripes 2010—the buses are multiple lateral transferors that move electrical objects to the right (to be imaged) and then to the left (after being imaged) and the push—pull stripes push move these buses to the left and to the right; (ii) bus motor 2020 and multi-clutch 2030 that move the stripes 2010 to the left and to the right and the multi-clutch 2030 converts the mechanical movement of bus motor 2020 to left and right movements; (iii) a container 2040 that included the electrical objects; (iv) bus platform 2050 that includes multiple buses—each bus has a long base and a sequence of evenly spaced projections whereas each pair of adjacent projections defined a space that can support a single electrical object; (v) a load element (referred to as load bus 2060) that loads the electrical objects to the buses so that their longitudinal axis is normal to the transferring axis of the buses; (vi) first imaging area 2070 that is imaged by imager 30 to obtain images of two opposite ends (for example—the two opposite ends of a capacitor—illustrated by boxes 2202 and 2204); (vii) bus un-loader 2080 that unloads the electrical objects after they are were imaged by imager 30 to be rotated (by 90 degrees) and are transferred (conveniently below the first imaging area) to the right to be elevated (by elevator 2090) towards the second imaging area 2100; (vii) second imaging area 2100 that is imaged by imager 30 to provide images of two sides (illustrated by boxes 2206 and 2208) of the objects; (viii) half flip unit 2110; (ix) third imaging area 2120 that is imaged by imager 30 to provide images of two other sides (illustrated by boxes 2210 and 2212); (x) delay unit 2130 (denoted processing) in which the objects are delayed while their images are processed; and (xi) sorting unit 170.

Two longitudinal transferors 2102 and 2112 are positioned at second and third imaging areas 3220 and 2120 and are used to longitudinally convey objects to the second imaging area, from the second imaging area to the third imaging area and out of the third imaging area.

Two different sides of the objects are obtained at different imaging areas. For example—assuming that the six sides are referred to as sides A, B, C, D, E, and F then sides A and C are imaged at the first imaging area, sides B and D are imaged at the second imaging area and sides E and F are imaged at the third imaging area.

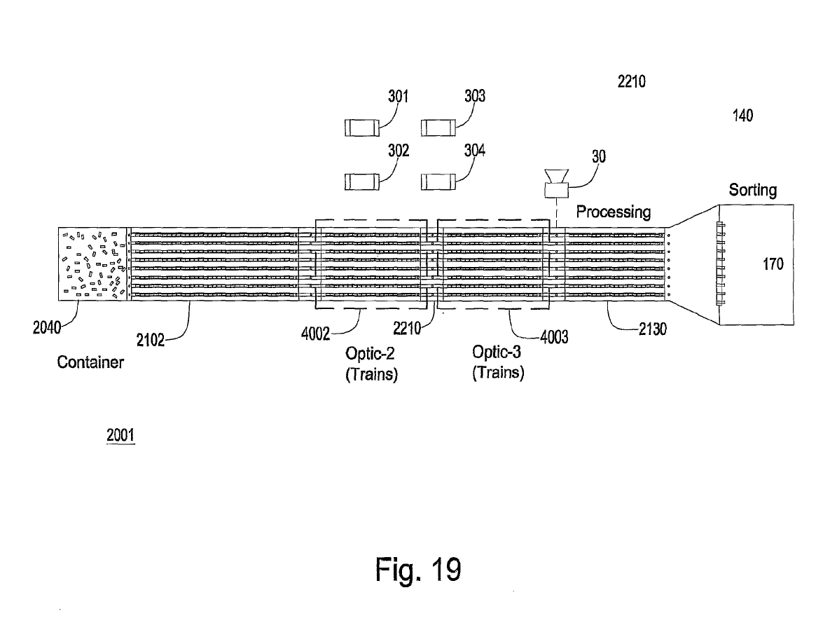

FIG. 19 illustrates system 2001 that images only four sides of the electrical objects thus does not include bus push-pull stripes; bus motor and multi-clutch; and first imaging area.

System 2001 includes (from left to right): (i) container 2040 that included the electrical objects; (iv) first longitudinal transferor 2102; (ii) second imaging area 2100 that is imaged by imager 30 to provide images of two sides (illustrated by boxes 2206 and 2208) of the objects; (viii) half flip unit 2110; (ix) third imaging area 2120 that is imaged by imager 30 to provide images of two other sides (illustrated by boxes 2210 and 2212); (x) delay unit 2130 (denoted processing) in which the objects are delayed while their images are processed; and (xi) sorting unit 170.

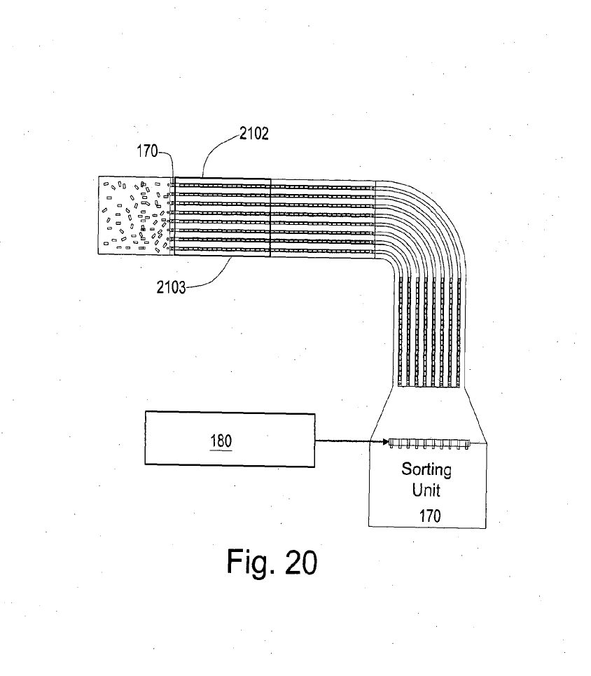

FIG. 20 illustrates system 3000 according to an embodiment of the inventor. System 3000 performs electrical testing of capacitors and sorts them according to their functionality.

System 3000 includes supply unit 170, longitudinal transferor 2102 and a sorting unit 170 that is equipped with test points that can electrically connect objects provided to sorting unit 170 and measurement devices 180 such as measurement device 3200.

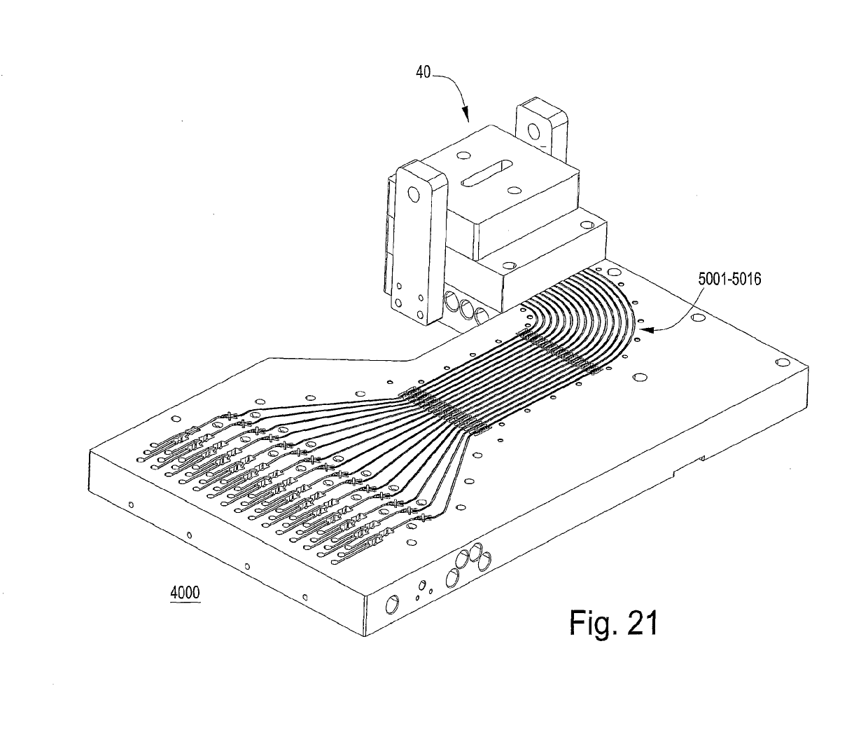

FIG. 21 illustrates system 4000 according to an embodiment of the invention.

System 4000 is used to filter out objects that are wider then required. Such objects as well as fractions of objects are directed toward tunnels that can be slightly wider then (or almost exactly the size of) the allowable width. Objects that are wider then this width get stuck. They can later be sucked out of the system or evacuated by other means. System 4000 includes supply element 40, multiple channels 5001-5016 and sorting unit 170.

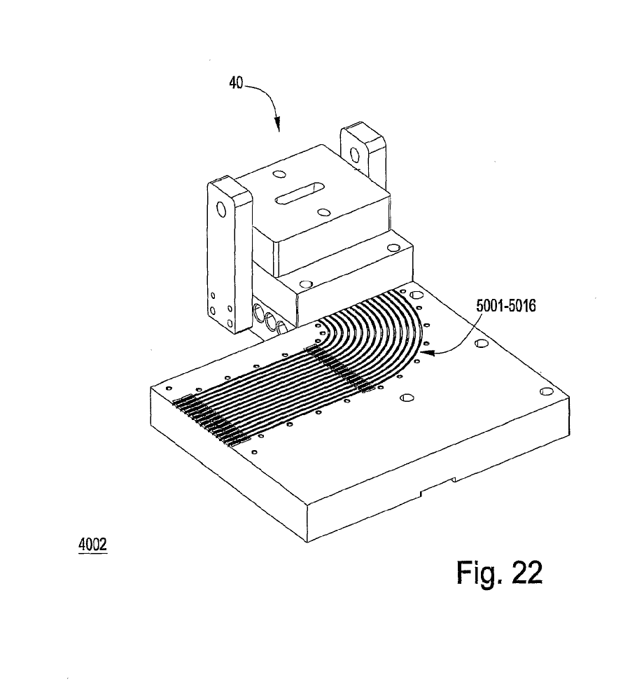

FIG. 22 illustrates system 4002 according to an embodiment of the invention. System 4002 does not include sorting unit. If objects are stuck they can be evacuated. It can include a movable portion that once removed exposed tunnels 5001-5016. System 4000 can also include such movable portion.

System 4000 is used to filter out objects that are wider then required. Such objects as well as fractions of objects are directed toward tunnels that can be slightly wider then (or almost exactly the size of) the allowable width. Objects that are wider then this width get stuck. They can later be sucked out of the system or evacuated by other means. System 4000 includes supply element 40, multiple channels 5001-5016 and sorting unit 170.

Furthermore, those skilled in the art will recognize that boundaries between the functionality of the above described operations merely illustrative. The functionality of multiple operations may be combined into a single operation, and/or the functionality of a single operation may be distributed in additional operations. Moreover, alternative embodiments may include multiple instances of a particular operation, and the order of operations may be altered in various other embodiments.

Thus, it is to be understood that the architectures depicted herein are merely exemplary, and that in fact many other architectures can be implemented which achieve the same functionality. In an abstract, but still definite sense, any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or intermedial components. Likewise, any two components so associated can also be viewed as being “operably connected,” or “operably coupled,” to each other to achieve the desired functionality.

In addition, the invention is not limited to physical devices or units implemented in non-programmable hardware but can also be applied in programmable devices or units able to perform the desired device functions by operating in accordance with suitable program code. Furthermore, the devices may be physically distributed over a number of apparatuses, while functionally operating as a single device.

However, other modifications, variations, and alternatives are also possible. The specifications and drawings are, accordingly, to be regarded in an illustrative rather than in a restrictive sense.

The word ‘comprising’ does not exclude the presence of other elements or steps then those listed in a claim. Moreover, the terms “front,” “back,” “top,” “bottom,” “over,” “under” and the like in the description and in the claims, if any, are used for descriptive purposes and not necessarily for describing permanent relative positions. It is understood that the terms so used are interchangeable under appropriate circumstances such that the embodiments of the invention described herein are, for example, capable of operation in other orientations than those illustrated or otherwise described herein.

Furthermore, the terms “a” or “an,” as used herein, are defined as one or more than one. Also, the use of introductory phrases such as “at least one” and “one or more” in the claims should not be construed to imply that the introduction of another claim element by the indefinite articles “a” or “an” limits any particular claim containing such introduced claim element to inventions containing only one such element, even when the same claim includes the introductory phrases “one or more” or “at least one” and indefinite articles such as “a” or “an.” The same holds true for the use of definite articles. Unless stated otherwise, terms such as “first” and “second” are used to arbitrarily distinguish between the elements such terms describe. Thus, these terms are not necessarily intended to indicate temporal or other prioritization of such elements. The mere fact that certain measures are recited in mutually different claims does not indicate that a combination of these measures cannot be used to advantage.

We claim:

1. A method for acquiring multiple images of objects, the method comprises:
longitudinally transferring objects through multiple tunnels of a first longitudinal transferor to a first imaging area; wherein the longitudinally transferring utilizes gas pressure differentials;
obtaining an image of a first side of the objects at the first imaging area;
rotating the objects by a first rotation module that rotates the objects about a longitudinal axis of the objects;
longitudinally transferring objects through multiple tunnels of a second longitudinal transferor to a second imaging area;
obtaining an image of a second side of the objects at the second imaging area;
rotating the object by a second rotation module that rotates the objects about the longitudinal axis of the objects;
longitudinally transferring objects through multiple tunnels of a third longitudinal transferor to a third imaging area;
obtaining an image of a third side of the objects at the third imaging area;
rotating the object by a third rotation module that rotates the objects about the longitudinal axis of the objects;
longitudinally transferring objects through multiple tunnels of a fourth longitudinal transferor to a fourth imaging area; and
obtaining an image of a fourth side of the objects at the fourth imaging area;
wherein at least one longitudinal transferor has a movable portion that when placed in a certain position exposes at least a substantial portion of at least one tunnel.

2. The method according to claim 1 wherein the objects are millimetric capacitors.

3. The method according to claim 1 comprising moving the movable portion to the certain position and cleaning the tunnels.

4. The method according to claim 1 comprising imaging the multiple objects via a transparent movable portion.

5. The method according to claim 1 wherein each longitudinal transferor comprises a movable portion that exposes all tunnels of each of the longitudinal transferor; and wherein the method further comprises moving the movable portion of each longitudinal transferor.

6. The method according to claim 1 comprising electrically testing an object by comparing an electrical characteristic of the object to an electrical characteristic of a reference object to provide an electrical test result.

7. The method according to claim 1 wherein the objects are capacitors; wherein the method comprises comparing a capacitance of a capacitor to a capacitance of a reference capacitor.

8. The method according to claim 1 comprising laterally transferring objects through multiple tunnels, each comprising substantially vertical sidewalls.

9. The method according to claim 1 comprising longitudinally transferring objects through multiple tunnels of the four longitudinal transferor that form four imaging areas; wherein each of the four longitudinal transferor is much longer than each rotation module.

10. The method according to claim 1 further comprising sorting, in parallel, multiple objects according to their functionality.

11. The method according to claim 1 further comprising supplying objects through an inlet of a supply element; and allowing the objects to fall through an outlet of the supply element towards tunnels of a first longitudinal transferor.

12. The method according to claim 1 further comprising laterally transferring objects through multiple tunnels of a lateral transferor to an additional imaging area; and obtaining images of two opposite sides of the objects that differ from sides of the objects that are imaged at the four imaging areas.

13. The method according to claim 12 comprising laterally transferring the objects between optical components that direct light from the opposite sides of the objects towards the imager.
